(19) United States
(12) Patent Application Publication
(10) Pub. No.: US 2025/0133950 A1
(43) Pub. Date: Apr. 24, 2025

(54) LIGHT EMITTING ELEMENT, METHOD FOR MANUFACTURING THE LIGHT EMITTING ELEMENT, AND DISPLAY DEVICE COMPRISING THE LIGHT EMITTING ELEMENT

(71) Applicant: Samsung Display Co., Ltd., Yongin-si (KR)

(72) Inventors: YUNKU JUNG, Yongin-si (KR); SANGYEOP LEE, Yongin-si (KR); WON-JUN PARK, Yongin-si (KR); CHUL SOON PARK, Yongin-si (KR); JONGWOO SHIN, Yongin-si (KR); Jungho JO, Yongin-si (KR)

(73) Assignee: Samsung Display Co., Ltd., Yongin-si (KR)

(21) Appl. No.: 18/782,389

(22) Filed: Jul. 24, 2024

(30) Foreign Application Priority Data
Oct. 24, 2023 (KR) 10-2023-0142832

(51) Int. Cl. H10K 85/30; C09K 11/06; H10K 50/15; H10K 50/16; H10K 71/10

(52) U.S. Cl. CPC H10K 85/341; C09K 11/06; H10K 71/10; C09K 2211/10; C09K 2211/188; H10K 50/15; H10K 50/16

(57) ABSTRACT

Embodiments provide a light emitting element that includes a first electrode, a second electrode disposed on the first electrode, an emission layer disposed between the first electrode and the second electrode and including quantum dots, a hole transport region disposed between the first electrode and the second electrode, and an electron transport region disposed between the first electrode and the second electrode, wherein the emission layer is disposed between the hole transport region and the electron transport region. At least one of the hole transport region and the electron transport region includes metal nanoparticles. The metal nanoparticles include a core containing a metal oxide, and a ligand bonded to the core, wherein the ligand includes an alkoxy group. The alkoxy group is derived from an oxygen-containing compound represented by Formula 1, which is explained in the specification.

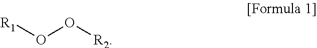

### CROSS-REFERENCE TO RELATED APPLICATION(S)

This application claims priority to and benefits of Korean Patent Application No. 10-2023-0142832 under 35 U.S.C. § 119, filed on Oct. 24, 2023, in the Korean Intellectual Property Office, the entire contents of which are incorporated herein by reference.

### BACKGROUND

### 1. Technical Field

The disclosure relates to a light emitting element including metal nanoparticles, a method for manufacturing the light emitting element, and a display device including the light emitting element.

### 2. Description of the Related Art

Light emitting elements have characteristics of converting electric energy into light energy. Among light emitting elements, a quantum dot light emitting element that includes quantum dots in an emission layer has high color purity and luminous efficiency and may have different colors. In a light emitting element, holes move to the emission layer through a hole transport region, and electrons move to the emission layer through an electron transport region. Research on smooth injection and transport of holes and electrons is being conducted for improving efficiency in a quantum dot light emitting element.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a light emitting element having excellent luminous efficiency and service life and a display device including the light emitting element.

Embodiments also provide a method for manufacturing the light emitting element having excellent manufacture reliability and efficiency.

According to an embodiment a light emitting element may include: a first electrode; a second electrode disposed on the first electrode; an emission layer disposed between the first electrode and the second electrode and including quantum dots; a hole transport region disposed between the first electrode and the second electrode; and an electron transport region disposed between the first electrode and the second electrode, wherein
the emission layer may be disposed between the hole transport region and the electron transport region; at least one of the hole transport region and the electron transport region may include metal nanoparticles; the metal nanoparticles may include a core including a metal oxide, and a ligand bonded to the core, the ligand including an alkoxy group; and the alkoxy group may be derived from an oxygen-containing compound represented by Formula 1:

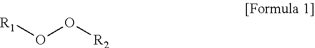

In Formula 1, R₁ and R₂ may each independently be a hydrogen atom, a substituted or unsubstituted alkyl group having 1 to 30 carbon atoms, or a substituted carbonyl group, and except that R₁ and R₂ may not be hydrogen atoms at a same time.

In an embodiment, the alkoxy group may be directly bonded to a surface of the core.

In an embodiment, the oxygen-containing compound may be selected from Compound Group 1, which is explained below.

In an embodiment, the ligand may be provided as multiple ligands, and at least one of the ligands may be different from the remainder.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1:

Zn_{(1-q)}Me_{q}O [Formula M-1]

In Formula M-1, q may be a real number from 0 to 0.3; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba.

In an embodiment, the electron transport region may be disposed between the first electrode and the emission layer; and the hole transport region may be disposed between the emission layer and the second electrode.

In an embodiment, the hole transport region may be disposed between the first electrode and the emission layer; and the electron transport region may be disposed between the emission layer and the second electrode.

In an embodiment, the electron transport region may include an electron injection layer and an electron transport layer disposed between the first electrode and the emission layer or between the emission layer and the second electrode; and at least one of the electron injection layer and the electron transport layer may include the metal nanoparticles.

In an embodiment, the hole transport region may include a hole injection layer and a hole transport layer disposed between the first electrode and the emission layer or between the emission layer and the second electrode; and at least one of the hole injection layer and the hole transport layer may include the metal nanoparticles.

According to an embodiment, a method for manufacturing a light emitting element may include: forming a first electrode; forming an emission layer on the first electrode; forming a second electrode on the emission layer; forming a hole transport region; and forming an electron transport region, wherein
one step among the forming of the hole transport region and the forming of the electron transport region may be performed between the forming of the first electrode and the forming of the emission layer; the remaining step among the forming of the hole transport region and the forming of the electron transport region may be performed between the forming of the emission layer and the forming of the second electrode; at least one of the forming of the hole transport region and the forming of the electron transport region may include providing a composition including metal nanoparticles; the metal nanoparticles may include a core including a metal oxide, and a ligand bonded to the core, the ligand including an alkoxy group; and the alkoxy group may be derived from an oxygen-containing compound represented by Formula 1:

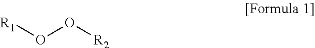

In Formula 1, R₁ and R₂ may each independently be a hydrogen atom, a substituted or unsubstituted alkyl group having 1 to 30 carbon atoms, or a substituted carbonyl group, except that R₁ and R₂ may not be hydrogen atoms at a same time.

In an embodiment, the method for manufacturing a light emitting element may further include producing the metal nanoparticles before the providing of the composition, wherein
the producing of the metal nanoparticles may include: preparing preliminary metal nanoparticles including the core and a preliminary ligand bonded to the core; providing the oxygen-containing compound to the preliminary metal nanoparticles; and bonding, to the core, the ligand generated by the dissociation of oxygen-oxygen bond of the oxygen-containing compound.

In an embodiment, the bonding of the ligand to the core may be performed at a first temperature at which heat is provided; the first temperature may be higher than an auto-decomposition temperature of the oxygen-containing compound; and the auto-decomposition temperature may be defined as a temperature at which the oxygen-containing compound is decomposed for itself to form an oxygen-containing radical.

In an embodiment, the preliminary ligand may be removed from the core in the bonding of the ligand to the core.

In an embodiment, the preliminary metal nanoparticles may be provided by being dispersed in an aqueous solvent containing a hydroxy group.

In an embodiment, the composition may be provided by an inkjet printing method or by a dispensing method.

In an embodiment, the oxygen-containing compound may be selected from Compound Group 1, which is described below.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1:

Zn_{(1-q)}Me_{q}O [Formula M-1]

In Formula M-1, q may be a real number from 0 to 0.3; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba.

According to an embodiment, a display device may include: a display element layer disposed on a base layer, wherein
the display element layer may include a light emitting element, and a pixel defining film in which a pixel opening may be defined; the light emitting element may include a first electrode disposed in the pixel opening, a second electrode disposed on the first electrode, an emission layer disposed between the first electrode and the second electrode and including quantum dots, a hole transport region disposed between the first electrode and the second electrode, and an electron transport region disposed between the first electrode and the second electrode; the emission layer may be disposed between the hole transport region and the electron transport region; at least one of the hole transport region and the electron transport region may include metal nanoparticles; the metal nanoparticles may include a core including a metal oxide, and a ligand bonded to the core, the ligand including an alkoxy group; and the alkoxy group may be derived from an oxygen-containing compound represented by Formula 1:

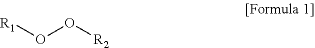

In Formula 1, R₁ and R₂ may each independently be a hydrogen atom, a substituted or unsubstituted alkyl group having 1 to 30 carbon atoms, or a substituted carbonyl group, except that R₁ and R₂ may not be hydrogen atoms at a same time.

In an embodiment, the alkoxy group may be directly bonded to a surface of the core.

In an embodiment, the oxygen-containing compound may be selected from Compound Group 1, which is explained below.

In an embodiment, the metal oxide may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1:

Zn_{(1-q)}Me_{q}O [Formula M-1]

In Formula M-1, q may be a real number from 0 to 0.3; and Me may be Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba.

In an embodiment, the electron transport region may include an electron injection layer, and an electron transport layer disposed between the first electrode and the emission layer or between the emission layer and the second electrode; and at least one of the electron injection layer and the electron transport layer may include the metal nanoparticles.

In an embodiment, the hole transport region may include a hole injection layer, and a hole transport layer disposed between the first electrode and the emission layer or between the emission layer and the second electrode; and at least one of the hole injection layer and the hole transport layer may include the metal nanoparticles.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic perspective view of a display device according to an embodiment;

FIG. 2 is a schematic cross-sectional view of a portion taken along line I-I′ of FIG. 1;

FIG. 3 is a schematic plan view of a display device according to an embodiment;

FIG. 4A is a schematic cross-sectional view of a portion taken along a virtual line II-II′ of FIG. 3;

FIG. 4B is a schematic cross-sectional view of the display device according to an embodiment;

FIGS. 5A to 5D are each a schematic cross-sectional view of a light emitting element according to an embodiment;

FIGS. 6A to 6D are each a schematic cross-sectional view of a light emitting element according to an embodiment;

FIG. 7 is a schematic cross-sectional view of a metal nanoparticle according to an embodiment;

FIG. 8 is an enlarged schematic view illustrating region XX′ in FIG. 7;

FIG. 9 is a schematic cross-sectional view of a metal nanoparticle according to an embodiment;

FIG. 10A is a flowchart of a method for manufacturing a light emitting element according to an embodiment;

FIG. 10B is a flowchart of a method for manufacturing a light emitting element according to an embodiment;

FIG. 11 is a schematic view of a step for manufacturing a light emitting element according to an embodiment;

FIG. 12 is a schematic cross-sectional view of a step for manufacturing a light emitting element according to an embodiment;

FIG. 13 is a schematic cross-sectional view of a step for manufacturing a light emitting element according to an embodiment;

FIG. 14 is an enlarged schematic view illustrating region AA′ in FIG. 12; and

FIG. 15 is a graph showing changes over time in brightness of the light emitting elements according to Comparative Examples and an Example.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and/or like reference characters refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device.

Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is unsubstituted or substituted with at least one substituent selected from the group consisting of a deuterium atom, a halogen atom, a hydroxy group, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may be substituted or unsubstituted. For example, a biphenyl group may be interpreted as an aryl group or it may be interpreted as a phenyl group substituted with a phenyl group.

In the specification, the term “bonded to an adjacent group to form a ring” may be interpreted as a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may be monocyclic or polycyclic. A ring that is formed by adjacent groups being bonded to each other may itself be connected to another ring to form a spiro structure.

In the specification, the term “an adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, or an iodine atom.

In the specification, an alkyl group may be linear, branched, or cyclic. The number of carbon atoms in an alkyl group may be 1 to 60, 1 to 50, 1 to 30, 1 to 20, 1 to 10, or 1 to 6. Examples of an alkyl group may include a methyl group, an ethyl group, an n-propyl group, an isopropyl group, a cyclopropyl group, an n-butyl group, an s-butyl group, a t-butyl group, an 1-butyl group, a 2-ethylbutyl group, a 3,3-dimethylbutyl group, a cyclobutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, a cyclopentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, a cycloheptyl group, an n-octyl group, a t-octyl group, a 2-ethyloctyl group, a 2-butyloctyl group, a 2-hexyloctyl group, a cyclooctyl group, a 3,7-dimethyloctyl group, an n-nonyl group, a cyclononyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, a cyclodecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, a norbornyl group, an 1-adamantyl group, a 2-adamantyl group, an isobornyl group, a bicycloheptyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

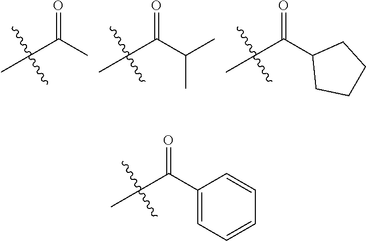

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, an oxy group may be an oxygen atom that is bonded to an alkyl group or an aryl group as defined above. An oxy group may be an alkoxy group or an aryl oxy group. An aryl group in the aryl oxy group may be the same as an example of an aryl group as described above. An alkoxy group may be linear, branched, or cyclic. The number of carbon atoms in an alkoxy group is not particularly limited, and may be, for example, 1 to 30, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a direct linkage may be a single bond.

In the specification, the symbols

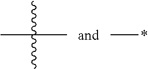

each represent a bond to a neighboring atom in a corresponding formula or moiety.

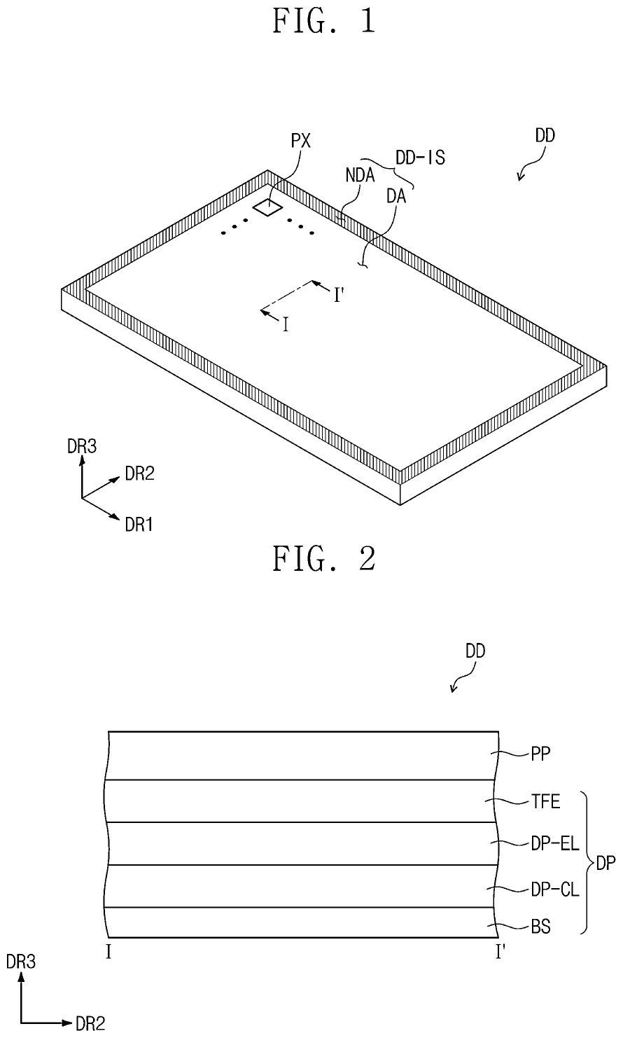

Hereinafter, a light emitting element and a display device including the light emitting element according to an embodiment will be described with reference to the drawings. FIG. 1 is a schematic perspective view of a display device according to an embodiment.

Referring to FIG. 1, the display device DD according to an embodiment may be activated by an electrical signal. For example, the display device DD may be a large-sized device such as a television, a monitor, or an outdoor billboard. In an embodiment, the display device DD may be a small or medium-sized device such as a personal computer, a laptop computer, a personal digital terminal, a car navigation system, a game console, a smart phone, a tablet, or a camera. These are merely provided as examples, and the display device DD may be included in other devices.

The display device DD may display an image (or a video) through a display surface DD-IS. The display surface DD-IS may be parallel to a plane that is defined by a first directional axis DR1 and a second directional axis DR2. The display surface DD-IS may include a display region DA and a non-display region NDA.

Pixels PX may be disposed in the display region DA, and the pixels PX may not be disposed in the non-display region NDA. The non-display region NDA may be defined by the edges of the display surface DD-IS. The non-display region NDA may surround the display region DA. However, embodiments are not limited thereto, and the non-display region NDA may be omitted, or the non-display region NDA may be disposed only on one side of the display region DA.

FIG. 1 illustrates that the display device DD has a display surface DD-IS that is flat. However, embodiments are not limited thereto. For example, the display surface DD-IS of the display device DD may be a curved display surface or a three-dimensional display surface. The three-dimensional display surface may include multiple display areas disposed in different directions.

FIG. 1 and the drawings described below illustrate the first directional axis DR1, a second directional axis DR2, and/or a third directional axis DR3, and the directions indicated by the first to third directional axes DR1, DR2 and DR3 described in this specification are relative terms and may be converted into other directions. The directions indicated by the first to third directional axes DR1, DR2 and DR3 may be described as first to third directions, and the same reference symbols may be used. In the specification, the first directional axis DR1 and the second directional axis DR2 may be orthogonal to each other, and the third directional axis DR3 may be the normal direction with respect to a plane that is defined by the first directional axis DR1 and the second directional axis DR2.

In the specification, a plan view may refer to a plane defined by the first directional axis DR1 and the second directional axis DR2, and a cross-sectional view may refer to a surface which is perpendicular to the plane defined by the first directional axis DR1 and the second directional axis DR2, and parallel to the third directional axis DR3. The display device DD may have a thickness direction that is parallel to a third direction DR3, which is the normal direction with respect to the plane defined by the first direction DR1 and the second direction DR2.

In the specification, a top surface (or a front surface) and a bottom surface (or a rear surface) of each member constituting the display device DD may be defined with respect to the third direction DR3. For example, among two surfaces facing each other with respect to the third direction DR3 in one member, a surface relatively adjacent to the display surface DD-IS may be defined as a front surface (or a top surface), and a surface spaced apart from the display surface DD-IS with the front surface (or the top surface) interposed therebetween may be defined as a rear surface (or a bottom surface). In the specification, the upper portion (or upper side) and the lower portion (or lower side) may be defined with respect to the third direction DR3, and the upper portion (or upper side) may be defined in a direction closer to the display surface DD-IS, and the lower portion (or lower side) may be defined in a direction away from the display surface DD-IS.

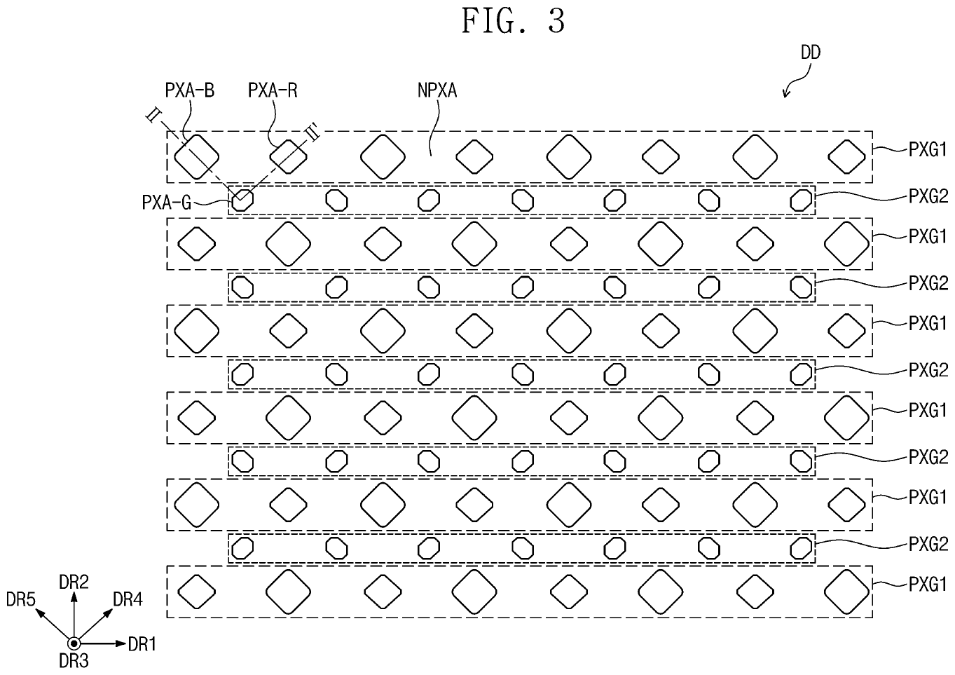

FIG. 2 is a schematic cross-sectional view of a portion taken along a virtual line I-I′ of FIG. 1. FIG. 2 may be a schematic cross-sectional view of a display device DD according to an embodiment.

The display device DD may include a display panel DP and an optical layer PP disposed on the display panel DP. The display panel DP may include a base layer BS, a circuit layer DP-CL disposed on the base layer BS, a display element layer DP-EL disposed on the circuit layer DP-CL, and an encapsulation layer TFE disposed on the display element layer DP-EL.

The display panel DP may generate a video. The display panel DP may be a light emitting display panel. For example, the display panel DP may be a quantum dot light emitting display panel that includes a quantum dot light emitting element.

The base layer BS may provide a base surface on which the circuit layer DP-CL is disposed. The base layer BS may be a rigid substrate or a flexible substrate that is bendable, foldable, rollable, or the like. The base layer BS may be a glass substrate, a metal substrate, or a polymer substrate. However, embodiments are not limited thereto, and the base layer BS may include an inorganic layer, an organic layer, or a composite material layer.

The circuit layer DP-CL may be disposed on the base layer BS. The circuit layer DP-CL may include an insulating layer, a semiconductor pattern, a conductive pattern, a signal line, etc. The insulating layer, the semiconductor layer, and the conductive layer may be formed on the base layer BS through methods such as coating or vapor deposition, and the insulating layer, the semiconductor layer, and the conductive layer may be selectively patterned by a photolithography process. The semiconductor pattern, the conductive pattern, and the signal line, which are included in the circuit layer DP-CL, may be formed.

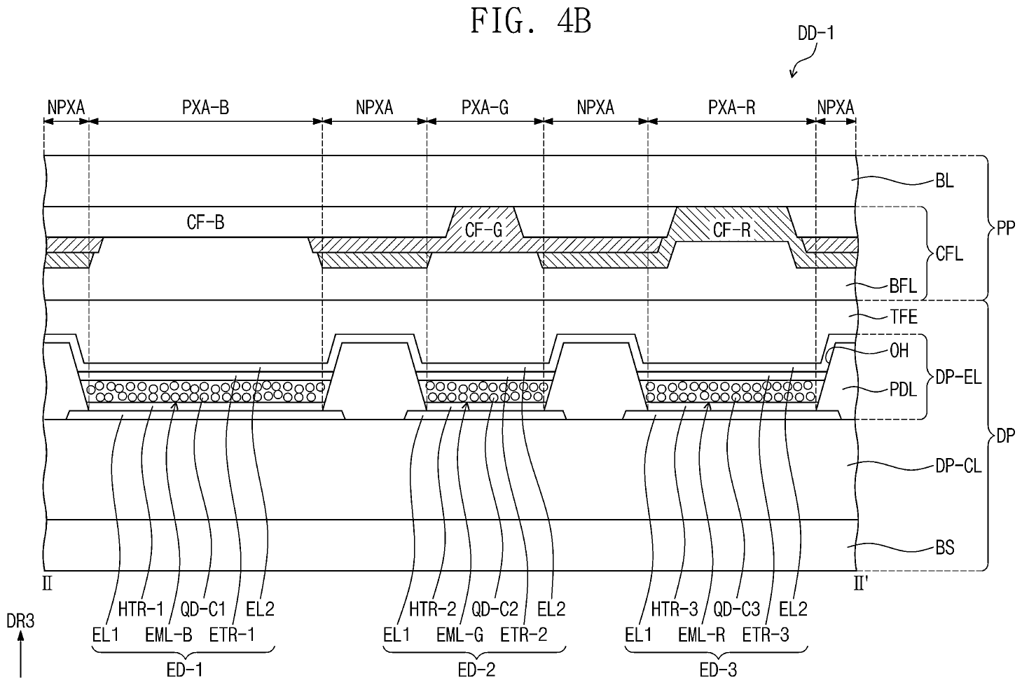

The display element layer DP-EL may be disposed on the circuit layer DP-CL. The display element layer DP-EL may include a pixel defining film PDL (see FIGS. 4A and 4B) and first to third light emitting elements ED-1, ED-2, and ED-3 (see FIGS. 4A and 4B), which will be described later. In an embodiment, the display element layer DP-EL may include an organic light emitting material, an inorganic light emitting material, an organic-inorganic light emitting material, quantum dots, quantum rod, a micro LED, or a nano LED. For example, the display element layer DP-EL may include quantum dots.

The encapsulation layer TFE may protect the display element layer DP-EL from foreign substances such as moisture, oxygen, and dust particles. The encapsulation layer TFE may include at least one inorganic layer. The encapsulation layer TFE may have a stacked structure of an inorganic layer, an organic layer, and an inorganic layer.

The optical layer PP may be disposed on the display panel DP to control light that is reflected in the display panel DP from an external light. The optical layer PP may include, for example, a polarization layer or a color filter layer. In an embodiment, although not shown in the figures, in an embodiment, the optical layer PP may be omitted.

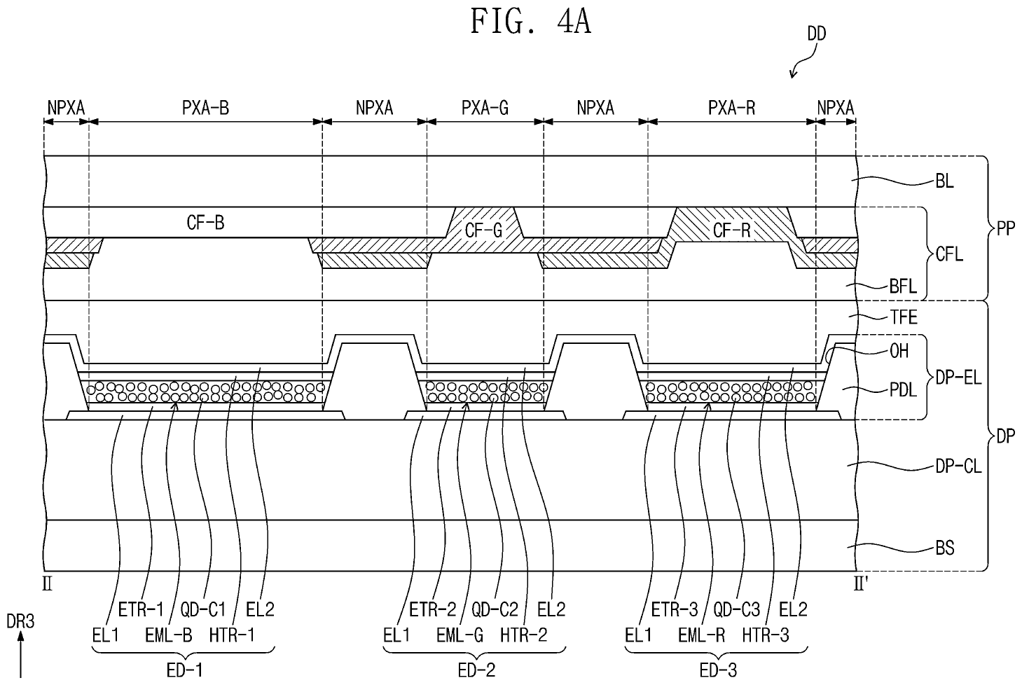

FIG. 3 is a schematic plan view of a display device DD according to an embodiment.

FIG. 4A is a schematic cross-sectional view of a portion taken along line II-II′ of FIG. 3. FIG. 3 may be a schematic plan view of a display region DA (see FIG. 1) of the display device DD.

FIG. 4A may be a schematic cross-sectional view of a portion of the display device DD according to an embodiment.

Referring to FIGS. 3 and 4A, the display device DD may include a peripheral region NPXA and light emitting regions PXA-R, PXA-G, and PXA-B. The light emitting regions PXA-R, PXA-G, and PXA-B may be a region that emits light respectively generated by the light emitting elements ED-1, ED-2, and ED-3. The light emitting regions PXA-R, PXA-G, and PXA-B may each be distinct from each other in a plan view.

The light emitting regions PXA-R, PXA-G, and PXA-B may be divided into multiple groups according to the colors of light generated from the light emitting elements ED-1, ED-2, and ED-3. FIGS. 3 and 4A illustrate three light emitting regions PXA-R, PXA-G, and PXA-B, which respectively emit red light, green light, and blue light as an example. For example, the display device DD may include the red light emitting region PXA-R, the green light emitting region PXA-G, and the blue light emitting region PXA-B that are separated from each other.

The display panel DP may include multiple light emitting elements ED-1, ED-2, and ED-3 which each emit light in different wavelength regions. The light emitting elements ED-1, ED-2, and ED-3 may each emit light having different colors. For example, the display panel DP may include a first light emitting element ED-1 that emits blue light, a second light emitting element ED-2 that emits green light, and a third light emitting element ED-3 that emits red light. However, embodiments are not limited thereto, and the first to third light emitting elements ED-1, ED-2, and ED-3 may emit light in a same wavelength region or at least one light emitting element may emit light in a wavelength region that is different from the remainder.

In the display device DD according to an embodiment illustrated in FIGS. 3 and 4A, the light emitting regions PXA-R, PXA-G, and PXA-B may each have areas that are different in size and shape from each other, according to the colors emitted from the emission layers EML-B, EML-G, and EML-R of the respective light emitting elements ED-1, ED-2, and ED-3. The blue light emitting region PXA-B of the first light emitting element ED-1, which emits blue light, may have the largest area, and the green light emitting region PXA-G of the second light emitting element ED-2, which emits green light, may have the smallest area. However, embodiments are not limited thereto, and the light emitting regions PXA-R, PXA-G, and PXA-B may each emit light having a different color other than red light, green light, and blue light. In an embodiment, the light emitting regions PXA-R, PXA-G, and PXA-B may each have a same area or they may have areas that are provided at different proportions from what is illustrated in FIG. 3.

The light emitting regions PXA-R, PXA-G, and PXA-B may each be a region separated by the pixel defining film PDL. The non-peripheral regions NPXA may be regions between the neighboring pairs of the light emitting regions PXA-R, PXA-G, and PXA-B, which correspond to the pixel defining film PDL. The light emitting regions PXA-R, PXA-G, and PXA-B may each correspond to a pixel.

The pixel defining film PDL may define the light emitting regions PXA-R, PXA-G, and PXA-B. The light emitting regions PXA-R, PXA-G, and PXA-B and the peripheral region NPXA may be separated by the pixel defining film PDL.

The blue light emitting regions PXA-B and the red light emitting regions PXA-R may be alternately arranged along the first directional axis DR1 to constitute a first group PXG1. The green light emitting regions PXA-G may be arranged along the first directional axis DR1 to constitute a second group PXG2. The first group PXG1 may be disposed to be spaced apart from the second group PXG2 in the second direction DR2. The first group PXG1 and the second group PXG2 may each be provided in multiples. The first groups PXG1 and the second groups PXG2 may be alternately arranged with respect to each other along the second directional axis DR2.

A red light emitting region PXA-R may be disposed to be spaced apart from one green light emitting region PXA-G in a direction of a fourth directional axis DR4. A blue light emitting region PXA-B may be disposed to be spaced apart from one green light emitting region PXA-G in a direction of a fifth directional axis DR5. The fourth directional axis DR4 may be a direction between the first directional axis DR1 and the second directional axis DR2. The fifth directional axis DR5 may be a direction crossing the fourth directional axis DR4 and inclined with respect to the second directional axis DR2.

An arrangement of the light emitting regions PXA-R, PXA-G, and PXA-B is not limited to the arrangement illustrated in FIG. 3. For example, in the light emitting regions PXA-R, PXA-G, and PXA-B, a red light emitting region PXA-R, a green light emitting region PXA-G, and a blue light emitting region PXA-B may be alternately arranged along the first directional axis DR1. The shapes of the light emitting regions PXA-R, PXA-G, and PXA-B in a plan view are not limited to the shapes shown in the figures, and may be defined as shapes that are different from the shapes shown in the figures.

In the display device DD (for example, as shown in FIG. 4A), the base layer BS may have a single-layered structure or a multi-layered structure. In an embodiment, the base layer BS may include a first synthetic resin layer, an intermediate layer in a multi-layered or a single-layered structure, and a second synthetic resin layer, which may be stacked in that order. The intermediate layer may be referred to as a base barrier layer. The intermediate layer may include a silicon oxide (SiOₓ) layer, and an amorphous silicon (a-Si) layer disposed on the silicon oxide layer, but embodiments are not limited thereto. For example, the intermediate layer may include at least one of a silicon oxide layer, a silicon nitride layer, a silicon oxynitride layer, and an amorphous silicon layer.

The first and second synthetic resin layers may each include a polyimide-based resin. Thee first and second synthetic resin layers may each include at least one of an acrylate-based resin, methacrylate-based resin, a polyisoprene-based resin, a vinyl-based resin, an epoxy-based resin, a urethane-based resin, a cellulose-based resin, a siloxane-based resin, apolyamide-based resin, and a perylene-based resin. In the specification, an “x-based” resin may represent a feature of including a functional group of “x”.

The circuit layer DP-CL may be disposed on the base layer BS, and the circuit layer DP-CL may include multiple transistors (not shown). The transistors (not shown) may each include a control electrode, an input electrode, and an output electrode. For example, the circuit layer DP-CL may include a switching transistor and a driving transistor for driving the first to third light emitting elements ED-1, ED-2, and ED-3 of the display element layer DP-EL.

The display element layer DP-EL may include the pixel defining film PDL and the first to third light emitting elements ED-1, ED-2, and ED-3. An opening OH may be defined in the pixel defining film PDL. The opening OH may be referred to as a pixel opening. The pixel defining film PDL may separate the first to third light emitting elements ED-1, ED-2, and ED-3. The emission layers EML-B, EML-G, and EML-R of the first to third light emitting elements ED-1, ED-2 and ED-3 may each be disposed in the openings OH defined in the pixel defining film PDL and separated from each other.

The pixel defining film PDL may be formed of a polymer resin. For example, the pixel defining film PDL may include a polyacrylate-based resin or a polyimide-based resin. In an embodiment, the pixel defining film PDL may further include an inorganic material in addition to the polymer resin. The pixel defining film PDL may include a light absorbing material or a black pigment or a black dye. The pixel defining film PDL including the black pigment or the black dye may implement a black pixel defining film. In forming the pixel defining film PDL, carbon black, etc. may be used as the black pigment or the black dye, but embodiments are not limited thereto.

In an embodiment, the pixel defining film PDL may be formed of inorganic materials. For example, the pixel defining film PDL may include an inorganic material such as silicon nitride (SiNₓ), silicon oxide (SiOₓ) or silicon oxynitride (SiOₓN_{y}).

In an embodiment, the first to third light emitting elements ED-1, ED-2, and ED-3 may each include a first electrode EL1, a second electrode EL2 disposed on the first electrode EL1, emission layers EML-B, EML-G, and EML-R disposed between the first electrode and the second electrode, electron transport regions ETR-1, ETR-2, and ETR-3, and hole transport regions HTR-1, HTR-2, and HTR-3. The electron transport regions ETR-1, ETR-2, and ETR-3 and the hole transport regions HTR-1, HTR-2, and HTR-3 may be spaced apart from each other with the emission layers EML-B, EML-G, and EML-R disposed therebetween.

Referring to FIG. 4A, the first to third light emitting elements ED-1, ED-2, and ED-3 may each include a first electrode EL1, a second electrode EL2 disposed on the first electrode EL1, emission layers EML-B, EML-G, and EML-R disposed between the first electrode and the second electrode EL2, electron transport regions ETR-1, ETR-2, and ETR-3 disposed between the first electrode EL1 and the emission layers EML-B, EML-G, and EML-R, and hole transport regions HTR-1, HTR-2, and HTR-3 disposed between the emission layers EML-B, EML-G, and EML-R, and the second electrode EL2.

At least a portion of the first electrode EL1 may be exposed in the opening OH of the pixel defining film PDL. The first electrode EL1 may have conductivity. The first electrode EL1 may be formed of a metal material, a metal alloy, or a conductive compound. The first electrode EL1 may be a cathode or an anode. However, embodiments are not limited thereto. The first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In an embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments are not limited thereto. The first electrode EL1 may include the above-described metal materials, combinations of at least two metal materials of the above-described metal materials, oxides of the above-described metal materials, or the like, but embodiments are not limited thereto. The thickness of the first electrode EL1 may be in a range of about 700 Å to about 10,000 Å. For example, the thickness of the first electrode EL1 may be in a range of about 1,000 Å to about 3,000 Å.

The second electrode EL2 may be a common electrode. For example, when the first electrode EL1 is an anode, the second electrode EL2 may be a cathode, and when the first electrode EL1 is a cathode, the second electrode EL2 may be an anode. The second electrode EL2 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgYb). In an embodiment, the second electrode EL2 may have a multi-layered structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, the resistance of the second electrode EL2 may be decreased.

The emission layers EML-B, EML-G, and EML-R may be disposed between the first electrode EL1 and the second electrode EL2. The first light emitting element ED-1 may include the first emission layer EML-B, the second light emitting element ED-2 may include the second emission layer EML-G, and the third light emitting element ED-3 may include the third emission layer EML-R. The first emission layer EML-B may include first quantum dots QD-C1. The second emission layer EML-G may include second quantum dots QD-C2. The third emission layer EML-R may include third quantum dots QD-C3.

The quantum dots QD-C1, QD-C2, and QD-C3 included in the emission layers EML-B, EML-G, and EML-R, respectively, may be stacked to form a layer. FIG. 4A illustrates that the quantum dots QD-C1, QD-C2, QD-C3 having a circular cross-section are arranged to form approximately two layers, but embodiments are not limited thereto. For example, the arrangement of the quantum dots QD-C1, QD-C2, and QD-C3 may vary with the thicknesses of the emission layers EML-B, EML-G, and EML-R, the shapes of the quantum dots QD-C1, QD-C2, and QD-C3 included in the emission layers EML-B, EML-G, and EML-R, the average diameter of the quantum dots QD-C1, QD-C2, and QD-C3, or the like. For example, in the emission layers EML-B, EML-G, and EML-R, the quantum dots QD-C1, QD-C2, and QD-C3 may be aligned to be adjacent to each other to form a single layer, or may be aligned to form multiple layers such as two or three layers.

The first quantum dots QD-C1 of the first light emitting element ED-1 may emit blue light. The second quantum dots QD-C2 of the second light emitting element ED-2 may emit green light. The third quantum dots QD-C3 of the third light emitting element ED-3 may emit red light. The quantum dots QD-C1, QD-C2, and QD-C3 may each include a core (not shown) and a shell (not shown) surrounding the core. In an embodiment the quantum dots QD-C1, QD-C2, and QD-C3 may each include a core-shell structure. The cores of the quantum dots QD-C1, QD-C2, and QD-C3 may include different materials from each other. In another embodiment, the cores of quantum dots QD-C1, QD-C2, and QD-C3 may include the same materials. Any two cores among the cores of the quantum dots QD-C1, QD-C2, and QD-C3 may include the same materials, and the remaining one core may include a different material from the others.

FIG. 4A illustrates that the first to third quantum dots QD-C1, QD-C2, and QD-C3 may have similar diameters, but embodiments are not limited thereto. The first to third quantum dots QD-C1, QD-C2, and QD-C3 may each have a different diameter. For example, the first quantum dots QD-C1 of the first light emitting element ED-1 that emits light in a relatively short wavelength range may have a relatively smaller average diameter than the second quantum dots QD-C2 of the second light emitting element ED-2 and the third quantum dots QD-C3 of the third light emitting element ED-3, which emit light in a relatively long wavelength region. The average diameter may be a diameter obtained by calculating an arithmetic mean of multiple quantum dots. The particle diameter of the quantum dot may be the average value of the widths of the quantum dot particles in a cross-section.

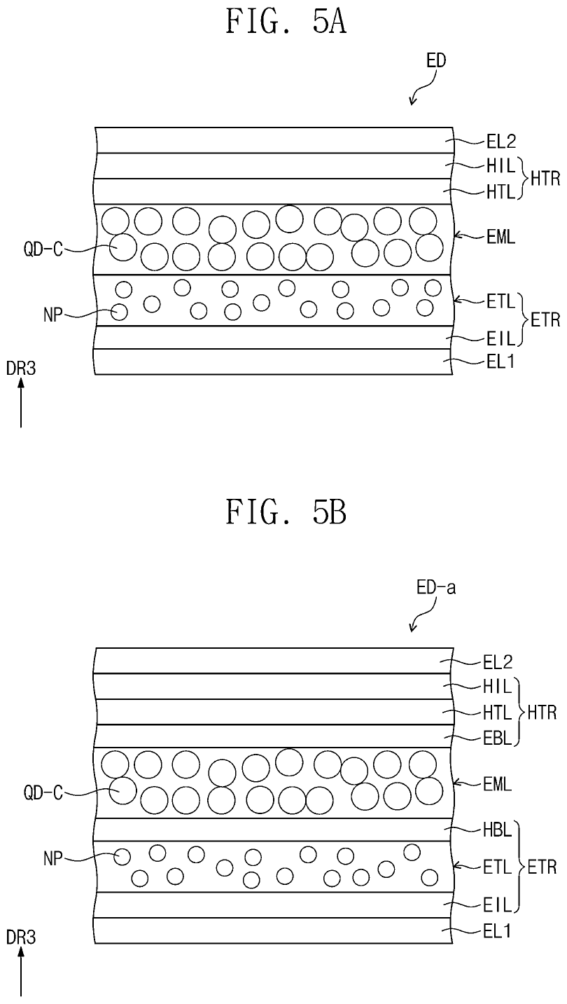

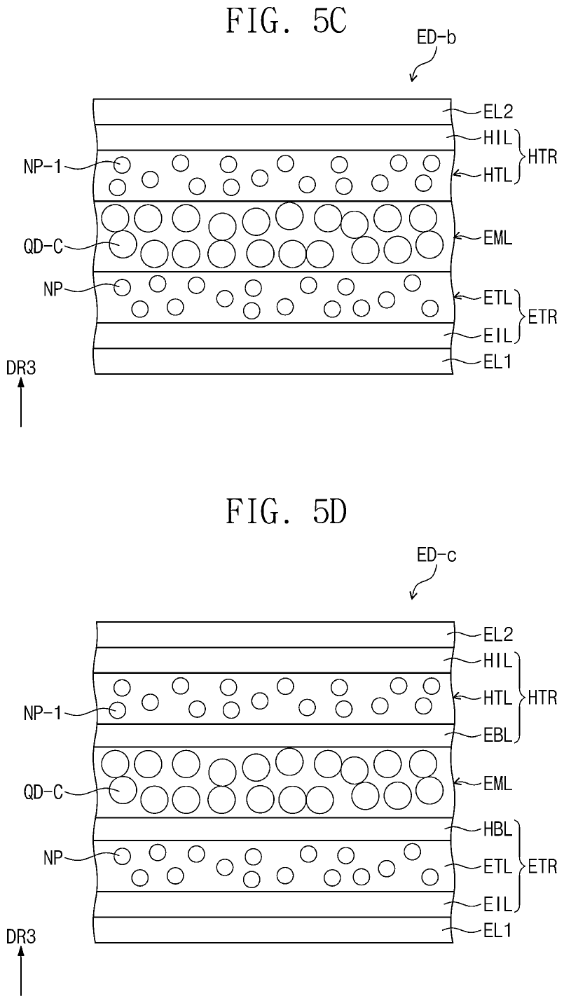

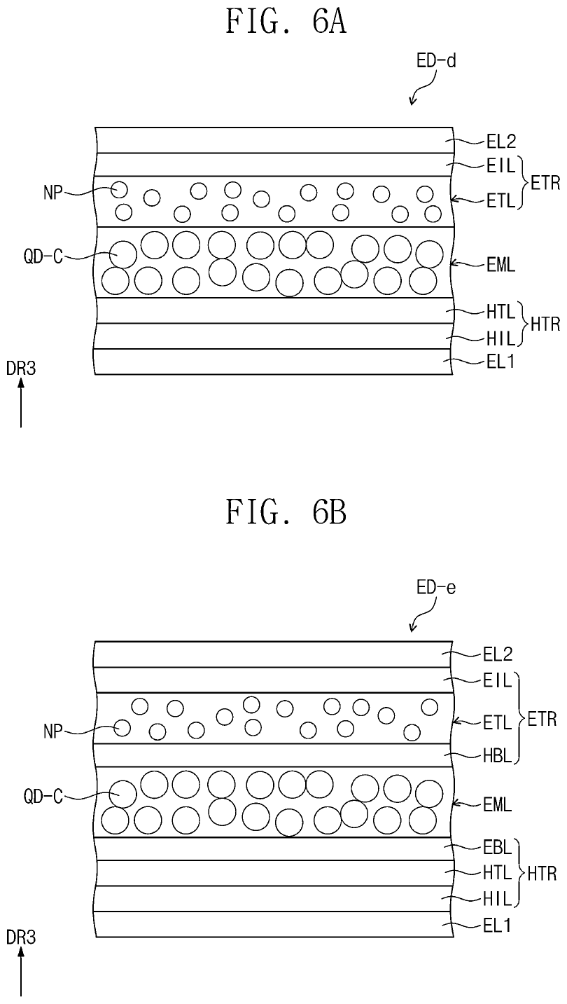

In an embodiment, at least one of the electron transport regions ETR-1, ETR-2, and ETR-3 or the hole transport regions HTR-1, HTR-2, and HTR-3 may include metal nanoparticles NP and NP-1 (see FIGS. 5A to 6D), which will be described later. In an embodiment, the metal nanoparticles NP and NP-1 (see FIGS. 5A to 6D) may include a core MC (see FIG. 7) and ligands LD (see FIG. 7) bonded to the core MC (see FIG. 7).

For example, the electron transport regions ETR-1, ETR-2, and ETR-3 may include multiple metal nanoparticles NP (see FIGS. 5A to 6D), and the metal nanoparticles NP (see FIGS. 5A to 6D) may be the same or at least one may be different from the others. The core MC (see FIG. 7) and/or the ligands LD (see FIG. 7) of the metal nanoparticles NP (FIGS. 5A to 6D) may be different from each other.

For example, the hole transport regions HTR-1, HTR-2, and HTR-3 may include metal nanoparticles NP-1 (see FIGS. 5C, 5D, 6C, and 6D), and the metal nanoparticles NP-1 (see FIG. 5C, 5D, 6C, and 6D) may be the same or at least one may be different from the others. The core MC (see FIG. 7) and/or the ligands LD (see FIG. 7) of the metal nanoparticles NP-1 (FIGS. 5C, 5D, 6C, and 6D) may be different from each other.

In an embodiment, the core MC (see FIG. 7) may include a metal oxide, and the ligands LD (see FIG. 7) may include alkoxy groups that are bonded to the core MC. Accordingly, the metal nanoparticles NP and NP-1 (see FIGS. 5A to 6D) may exhibit excellent stability over time by eliminating surface defects, and may be provided by an inkjet printing method or a dispensing method. The metal nanoparticles NP and NP-1 (see FIGS. 5A to 6D) exhibit excellent charge transport/injection characteristics by eliminating surface defects, and may contribute to improving the efficiencies and service lives of the light emitting elements ED-1, ED-2, and ED-3. Metal nanoparticles NP and NP-1 (see FIGS. 5A to 6D) will be described later in more detail.

The electron transport regions ETR-1, ETR-2, and ETR-3 of the first to third light emitting elements ED-1, ED-2 and ED-3 may be disposed in the openings OH and separated from each other. The first light emitting element ED-1 may include a first electron transport region ETR-1, the second light emitting element ED-2 may include a second electron transport region ETR-2, and the third light emitting element ED-3 may include a third electron transport region ETR-3.

The first and second electron transport regions ETR-1, ETR-2, and ETR-3 may each be a layer consisting of a single material, a layer including different materials, or a structure including multiple layers formed of different materials. A thickness of each of the first to third electron transport regions ETR-1, ETR-2, and ETR-3 may each independently be, for example, in a range of about 300 Å to about 1,500 Å. For example, the thickness of each of the first to third electron transport regions ETR-1, ETR-2, and ETR-3 may each independently be in a range of about 1,000 Å to about 1,500 Å.

The first to third electron transport regions ETR-1, ETR-2, and ETR-3 may include electron injection materials and/or electron transport materials of the related art. For example, the first to third electron transport regions ETR-1, ETR-2, and ETR-3 include the metal nanoparticles NP (see FIGS. 5A to 6D) of an embodiment, and may further include electron injection materials of the related art and/or electron transport materials of the related art.

In an embodiment, the first to third electron transport regions ETR-1, ETR-2, and ETR-3 may include an anthracene-based compound. In another embodiment, the first to third electron transport regions ETR-1, ETR-2, and ETR-3 may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), beryllium bis(benzoquinolin-10-olate) (Bebg₂), 9,10-di(naphthalene-2-yl)anthracene (ADN), 1,3-bis[3,5-di(pyridin-3-yl)phenyl]benzene (BmPyPhB), and a mixture thereof. In another embodiment, the first to third electron transport regions ETR-1, ETR-2, and ETR-3 may include 2,9-dimethyl-4,7-diphenyl-1,10-phenanthroline (BCP), diphenyl(4-(triphenylsilyl)phenyl)phosphine oxide (TSPO1), 4,7-diphenyl-1,10-phenanthroline (Bphen), or the like.

The hole transport regions HTR-1, HTR-2, and HTR-3 of the first to third light emitting elements ED-1, ED-2 and ED-3 may be disposed in the openings OH and separated from each other. The first light emitting element ED-1 may include a first hole transport region HTR-1, the second light emitting element ED-2 may include a second hole transport region HTR-2, and the third light emitting element ED-3 may include a third hole transport region HTR-3.

The first to third hole transport regions HTR-1, HTR-2, and HTR-3 may each be a layer consisting of a single material, a layer including different materials, or a structure including multiple layers including different materials. The first to third hole transport regions HTR-1, HTR-2, and HTR-3 may each independently have a thickness of in a range of about 50 Å to about 15,000 Å. For example, the hole transport regions HTR-1, HTR-2, and HTR-3 may each independently have a thickness of in a range of about 100 Å to about 10,000 Å. For example, the hole transport regions HTR-1, HTR-2, and HTR-3 may each independently have a thickness of in a range of about 100 Å to about 5,000 Å.

The first to third hole transport regions HTR-1, HTR-2, and HTR-3 may include hole injection materials and/or hole transport materials of the related art. For example, the first to third hole transport regions HTR-1, HTR-2, and HTR-3 may include the metal nanoparticles NP-1 (see FIGS. 5C, 5D, 6C, and 6D) according to an embodiment, and may further include electron injection materials and/or electron transport materials of the related art.

The first to third hole transport regions HTR-1, HTR-2, and HTR-3 may each independently include, for example, a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine](m-MTDATA), 4,4′,4″-tris(N,N-diphenylamino)triphenylamine (TDATA), 4,4′,4″-tris[N,-(2-naphthyl) -N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N-di(naphthalene-1-yl)-N,N-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

In embodiments, the first to third hole transport regions HTR-1, HTR-2, and HTR-3 may each independently include carbazole derivatives such as N-phenyl carbazole and polyvinyl carbazole, fluorene derivatives, N,N-bis(3-methylphenyl)-N,N-diphenyl-[1,1-biphenyl]-4,4′-diamine (TPD), triphenylamine derivatives such as 4,4′,4″-tris(N-carbazolyl)triphenylamine (TCTA), N,N-di(naphthalene-1-yl)-N,N-diphenyl-benzidine (NPB), 4,4′-cyclohexylidene bis[N,N-bis(4-methylphenyl)benzenamine](TAPC), 4,4′-bis[N,N-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP), etc.

The encapsulation layer TFE may include at least one inorganic film (hereinafter, an encapsulation-inorganic film). The encapsulation layer TFE may also include at least one organic film (hereinafter, an encapsulation-organic film) and at least one encapsulation-inorganic film.

The encapsulation-inorganic film may protect the display element layer DP-EL from moisture and/or oxygen, and the encapsulation-organic film may protect the display element layer DP-EL from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The optical layer PP may include a base substrate BL and a color filter layer CFL. The base substrate BL may provide a base surface on which the color filter layer CFL is disposed. The base substrate BL may be a glass substrate, a metal substrate, a plastic substrate, etc. However, embodiments are not limited thereto, and the base substrate BL may include an inorganic layer, an organic layer, or a composite material layer.

The color filter layer CFL may include first to third filters CF-B, CF-G, and CF-R. The first to third filters CF-B, CF-G, and CF-R may be respectively disposed corresponding to the first to third light emitting elements ED-1, ED-2, and ED-3. For example, the first filter CF-B may be a blue filter, the second filter CF-G may be a green filter, and the third filter CF-R may be a red filter. The first to third filters CF-B, CF-G, and CF-R may be disposed to respectively correspond to the first to third light emitting regions PXA-B, PXA-G, and PXA-R.

The first to third filters CF-B, CF-G, and CF-R may each include a polymer photosensitive resin, and a pigment or a dye. The first filter CF-B may include a blue pigment or a blue dye, the second filter CF-G may include a green pigment or a green dye, and the third filter CF-R may include a red pigment or a red dye. However, embodiments are not limited thereto, and the first filter CF-B may not include a pigment or dye. The first filter CF-B may include a polymer photosensitive resin, but not include a pigment or a dye. The first filter CF-B may be transparent. The first filter CF-B may be formed of a transparent photosensitive resin.

The color filter layer CFL may further include a buffer layer BFL. For example, the buffer layer BFL may serve as a protective layer which protects the first to third filters CF-B, CF-G, and CF-R. The buffer layer BFL may be an inorganic material layer that includes at least one inorganic material selected from silicon nitride, silicon oxide, and silicon oxynitride. The buffer layer BFL may be formed of a single layer or of multiple layers.

In an embodiment, the second filter CF-G and the third filter CF-R may each be a yellow filter. The second filter CF-G and the third filter CF-R may not be separated and may be provided as one filter.

Although not shown in the drawings, the color filter layer CFL may further include a light shielding part (not shown). The light shielding part may be a black matrix. The light shielding part (not shown) may include an organic light shielding material or an inorganic light shielding material including a black pigment or dye. The light shielding part (not shown) may prevent light leakage, and may separate boundaries between the adjacent filters CF-B, CF-G, and CF-R.

FIG. 4B is a schematic cross-sectional view of a display device DD-1 according to another embodiment. In the description of FIG. 4B, the features which have been previously described with reference to FIGS. 1 to 4A will not be described again, and the differing features will be described.

The display device DD-1 illustrated in FIG. 4B is different from the display device DD that is shown in FIG. 4A at least in the positions of the hole transport regions HTR-1, HTR-2, HTR-3 and the electron transport regions ETR-1, ETR-2, and ETR-3. FIG. 4A illustrates that the electron transport regions ETR-1, ETR-2, and ETR-3 are disposed on the lower side of the emission layer EML-B, EML-G, and EML-R, and FIG. 4B illustrates that the electron transport regions ETR-1, ETR-2, and ETR-3 are disposed on the upper side of the emission layer EML-B, EML-G, and EML-R.

Referring to FIG. 4B, each of the first to third light emitting elements ED-1, ED-2, and ED-3 may include a first electrode EL1, hole transport regions HTR-1, HTR-2, and HTR-3 disposed on the first electrode EL1, emission layers EML-B, EML-G, and EML-R disposed on hole transport regions HTR-1, HTR-2, and HTR-3, electron transport regions ETR-1, ETR-2, and ETR-3 disposed on the emission layers EML-B, EML-G, and EML-R, and a second electrode EL2 disposed on the electron transport regions ETR-1, ETR-2, and ETR-3.

FIGS. 5A to 6D are each a schematic cross-sectional views of light emitting elements ED, and ED-a to ED-g according to embodiments. At least one among the first to third light emitting elements ED-1, ED-2, and ED-3 illustrated in FIG. 4A may have a structure according to one of the light emitting elements ED, ED-a, ED-b, and ED-c illustrated in FIGS. 5A to 5D. At least one of the first to third light emitting elements ED-1, ED-2, and ED-3 illustrated in FIG. 4B may have a structure according to one of the light emitting elements ED-d, ED-e, ED-f, and ED-g illustrated in FIGS. 6A to 6D.

In an embodiment, FIGS. 5A to 5D respectively illustrate light emitting elements ED, ED-a, ED-b, and ED-c, each including an electron transport region ETR disposed between a first electrode EL1 and an emission layer EML and a hole transport region HTR disposed between the emission layer EML and a second electrode EL2. In another embodiment, FIGS. 6A to 6D respectively illustrate light emitting elements ED-d, ED-e, ED-f, and ED-g, each including a hole transport region HTR disposed between a first electrode EL1 and an emission layer EML and an electron transport region ETR disposed between the emission layer EML and a second electrode EL2.

Referring to FIGS. 5A to 6D, the electron transport region ETR may include at least the electron injection layer EIL, and the electron transport layer ETL. Referring to FIGS. 5A to 5D, the electron injection layer EIL may be disposed on the first electrode EL1, and the electron transport layer ETL may be disposed on the electron injection layer EIL. Referring to FIGS. 5B and 5D, the electron transport region ETR may further include a hole blocking layer HBL disposed between the hole transport layer HTL and the emission layer EML.

Referring to FIGS. 6A to 6D, the electron transport layer ETL may be disposed on the emission layer EML, and the electron injection layer EIL may be disposed on the electron transport layer ETL. Referring to FIGS. 6B and 6D, the electron transport region ETR may further include a hole blocking layer disposed between the emission layer EML and the electron transport layer ETL. Although not shown in the drawings, the electron injection layer EIL may be omitted.

At least one of the electron injection layer EIL, the electron transport layer ETL, and the hole blocking layer HBL may include the metal nanoparticles according to an embodiment. For example, at least one of the electron injection layer EIL or the electron transport layer ETL may include the metal nanoparticles NP according to an embodiment. FIGS. 5A to 6D illustrate that the electron transport layer ETL includes the metal nanoparticles NP according to an embodiment, but embodiments are not limited thereto.

Referring to FIGS. 5A to 6D, the hole transport region HTR may include the hole injection layer HIL and the hole transport layer HTL. Referring to FIGS. 5A to 5D, the hole transport layer HTL may be disposed on the emission layer EML, and the hole injection layer HIL may be disposed on the hole transport layer HTL. Referring to FIGS. 5B and 5D, the hole transport region HTR may further include an electron blocking layer EBL disposed between the emission layer EML and the hole transport layer HTL. Referring to FIGS. 6A to 6D, the hole injection layer HIL may be disposed on the first electrode EL1, and the hole transport layer HTL may be disposed on the hole injection layer HIL. Referring to FIGS. 6B and 6D, the hole transport region HTR may further include an electron blocking layer EBL disposed between the hole transport layer HTL and the emission layer EML.

At least one of the hole injection layer HIL, the hole transport layer HTL, and the electron blocking layer EBL may include the metal nanoparticles NP-1 of an embodiment. For example, at least one of the hole injection layer HIL or the hole transport layer HTL may include the metal nanoparticles NP-1 according to an embodiment. FIGS. 5C, 5D, 6C, and 6D illustrate that the hole transport layer HTL includes the metal nanoparticles NP-1 according to an embodiment, but embodiments are not limited thereto.

The emission layer EML may include quantum dots QD-C. The description of quantum dots QD-C may be the same for the first to third quantum dots QD-C1, QD-C2, and QD-C3 illustrated in FIGS. 4A and 4B.

In the specification, the quantum dots QD-C may be a crystal of a semiconductor compound. The quantum dots QD-C may emit light having various emission wavelengths depending on a size of crystal. For example, quantum dots QD-C may have a diameter in a range of about 1 nm to about 10 nm.

The quantum dots QD-C may be synthesized by a wet chemical process, a metal organic chemical vapor deposition process, a molecular beam epitaxy process, a similar process thereto, or the like. The wet chemical process is a method in which a precursor material is mixed with an organic solvent to grow particle crystals of the quantum dots QD-C. When the crystals grow, the organic solvent may naturally serve as a dispersant coordinated on the surface of crystals of the quantum dots QD-C and control the growth of the crystals. Thus, the wet chemical process may control the growth of particles of the quantum dots QD-C through a process which is more readily performed than vapor deposition methods, such as metal organic chemical vapor deposition (MOCVD) or molecular beam epitaxy (MBE), and which may be performed at low costs.

The quantum dots may include: a Group II-VI semiconductor compound; a Group I-II-VI semiconductor compound; a Group I-II-IV-VI semiconductor compound; a Group III-V semiconductor compound; a Group III-VI semiconductor compound; a Group 1-II-VI semiconductor compound; a Group IV-VI semiconductor compound; a Group II-IV-V semiconductor compound; a Group IV element or compound; or any combination thereof. In the specification, the term “Group” refers to a group in the IUPAC periodic table.

Examples of a Group II-VI compound may include: a binary compound such as CdS, CdSe, CdTe, ZnS, ZnSe, ZnTe, ZnO, HgS, HgSe, HgTe, MgSe, or MgS; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; and a quaternary compound such as CdZnSeS, CdZnSeTe, CdZnSTe, CdHgSeS, CdHgSeTe, CdHgSTe, HgZnSeS, HgZnSeTe, or HgZnSTe; and any combination thereof.

In an embodiment, a Group II-VI semiconductor compound may further include a Group I element and/or a Group IV element. Examples of a Group 1-II-VI compound may include CuSnS or CuZnS. Examples of a Group II-IV-VI compound may include ZnSnS. Examples of a Group I-II-IV-VI compound may include a quaternary compound such as Cu₂ZnSnS₂, Cu₂ZnSnS₄, Cu₂ZnSnSe₄, Ag₂ZnSnS₂, and any combination thereof.

Examples of a Group III-V compound may include: a binary compound such as GaN, GaP, GaAs, GaSb, AlN, AlP, AlAs, AlSb, InN, InP, InAs, or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb; or any combination thereof. In an embodiment, a Group III-V semiconductor compound may further include a Group II element. Examples of a Group III-V semiconductor compound further including the Group II element may include InZnP, InGaZnP, InAlZnP, or the like.

Examples of a Group III-VI semiconductor compound may include: a binary compound such as GaS, Ga₂S₃, GaSe, Ga₂Se₃, GaTe, InTe, InS, InSe, In₂S₃, or In₂Se₃; a ternary compound such as InGaS₃ or InGaSe₃; and any combination thereof.

Examples of a Group 1-III-VI semiconductor compound may include: a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, or AgAlO₂; a quaternary compound such as AgInGaS₂ or AgInGaSe₂; and any combination thereof.

Examples of a Group IV-VI compound may include: a binary compound such as SnS, SnSe, SnTe, PbS, PbSe, or PbTe; a ternary compound such as SnSeS, SnSeTe, SnSTe, PbSeS, PbSeTe, PbSTe, SnPbS, SnPbSe, or SnPbTe; a quaternary compound such as SnPbSSe, SnPbSeTe, or SnPbSTe; and any combination thereof.

Examples of the Group II-IV-V compound may include a ternary compound such as ZnSnP, ZnSnP₂, ZnSnAs₂, ZnGeP₂, ZnGeAs₂, CdSnP₂, CdGeP₂, and any combination thereof.

Examples of a Group IV element or compound may include: a single element material such as Si and Ge; a binary compound such as SiC or SiGe; and any combination thereof.

Each element included in a compound such as a binary compound, a ternary compound, or a quaternary compound may be present in a particle with a uniform or non-uniform concentration distribution. For example, a formula may indicate the elements that are included in the compounds, but an elemental ratio in the compound may vary. For example, AgInGaS₂ may indicate AgInxGa₁₋ₓS₂ (where x is a real number from 0 to 1).

In an embodiment, the quantum dots QD-C may have a single structure in which the concentration of each element included in the quantum dots QD-C is uniform. In another embodiment, the quantum dots QD-C may have a core-shell structure in which one quantum dot surrounds another quantum dot. For example, a material included in the core may be different from a material included in the shell.

The shell of each of the quantum dots QD-C may serve as a protection layer to prevent the chemical deformation of the core to maintain semiconductor properties, and/or may serve as a charging layer to impart electrophoretic properties to the quantum dot. The shell may have a single layer or multiple layers. A quantum dot that has a core/shell structure may have a concentration gradient in which the concentration of an element that is present in the shell decreases toward the core.

An example of a shell of the quantum dots QD-C may include a metal oxide, a non-metal oxide, a semiconductor compound, or any combination thereof. Examples of a metal oxide or a non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound such as MgAl₂O₄, CoFe₂O₄, NiFe₂O₄, or CoMn₂O₄; and any combination thereof. Examples of a semiconductor compound may include a Group III-VI semiconductor compound; a Group II-VI semiconductor compound; a Group III-V semiconductor compound; a Group III-VI semiconductor compound; a Group 1-III-VI semiconductor compound; a Group IV-VI semiconductor compound; and any combination thereof. For example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AlP, AlSb, and any combination thereof.

The quantum dots QD-C may have a full width of half maximum (FWHM) of an emission spectrum less than or equal to about 45 nm. For example, the quantum dots QD-C may have a FWHM of an emission spectrum less than or equal to about 40 nm. For example, the quantum dots QD-C may have a FWHM of an emission spectrum less than or equal to about 30 nm. When the FWHM of an emission spectrum is within any of these ranges, color purity or color reproducibility may be enhanced. Light emitted through the quantum dots QD-C may be emitted in all directions, so that a wide viewing angle may be improved. The quantum dots QD-C may be in the form of spherical particles, pyramidal particles, multi-arm particles, or cubic particles, or the quantum dots QD-C may be nanoparticles, nanotubes, nanowires, nanofibers, nanoplate particles, etc.

As the sizes of the quantum dots QD-C are adjusted or the elemental ratio in the compound constituting the quantum dots QD-C is adjusted, an energy band gap may be adjusted, and thus light in various wavelength ranges may be obtained in the emission layer EML including the quantum dots QD-C. Therefore, the quantum dots as described above (using different sizes of quantum dots or different elemental ratios in the quantum dot compounds) are used, and thus the light emitting elements ED, and ED-a to ED-g, which emit light in various wavelengths, may be implemented. For example, the adjustment of the size of the quantum dots QD-C or the elemental ratio in the compound constituting the quantum dots QD-C may be selected to emit red light, green light, and/or blue light. The quantum dots QD-C may be configured to emit white light by combining various colors of light.

The metal nanoparticles NP (see FIGS. 5A to 6D) included in the electron transport region ETR and the metal nanoparticles NP-1 (see FIGS. 5C, 5D, 6C, and 6D) included in the hole transport region HTR may be the same as or different from each other. Hereinafter, the description of the metal nanoparticles NP and NP-a may be the same as the metal nanoparticles NP (see FIGS. 5A to 6D) included in the electron transport region ETR and the metal nanoparticles NP-1 (see FIGS. 5C, 5D, 6C, and 6D) included in the hole transport region HTR.

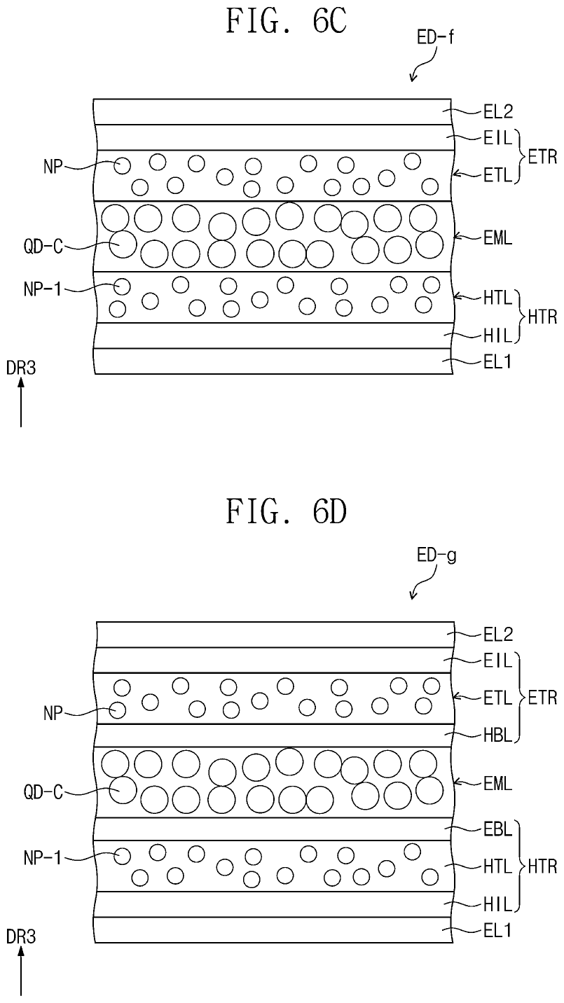

FIG. 7 is a schematic cross-sectional view of the metal nanoparticles NP according to an embodiment. FIG. 8 is an enlarged schematic view of region XX′ in FIG. 7. The metal nanoparticles NP according to an embodiment may include a core MC and ligands LD bonded to the core MC. FIG. 7 illustrates eight ligands LD, but the number of ligands LD bonded to the core MC is not limited thereto. The position of the ligands LD bonded in FIG. 7 is only an example, and embodiments are not limited thereto.

In an embodiment, the core MC of the metal nanoparticles NP may include a metal oxide. In an embodiment, the metal oxide of the core MC may include at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or the metal oxide may be represented by Formula M-1:

Zn_{(1-q)}Me_{q}O [Formula M-1]

In Formula M-1, q may be a real number from 0 to 0.3. In Formula M-1, Me may be Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba. For example, the core MC of the metal nanoparticles NP may include at least one of ZnO, ZnMgO, ZnSnO, ZnFeO, ZnGeO, ZnPbO, ZnCrO, SnO₂, or TiO₂.

In an embodiment, the surface MC_SF of the core MC in the metal nanoparticle NP may be modified with the ligands LD. The ligands LD may each include a head part HP bonded to the surface MC_SF of the core MC in the metal nanoparticle NP and a tail part TP bonded to the head part HP. In the ligands LD, the head part HP may be a part directly bonded to the metal nanoparticle NP. The head part HP may include an oxygen atom. The tail part TP may include a carbon atom bonded to the oxygen atom of the head part HP. The oxygen atom of the head part HP and the carbon atom of the tail part TP may constitute an alkoxy group. The tail part TP may include a substituted or unsubstituted alkyl group or a substituted carbonyl group. The carbon atom of the tail part TP may be a carbon atom constituting a substituted or unsubstituted alkyl group, or a carbon atom constituting a substituted carbonyl group.

The ligands LD may include alkoxy groups. The alkoxy group may be directly bonded to the surface MC_SF of the core MC of the metal nanoparticle NP. The alkoxy group may be derived from an oxygen-containing compound represented by Formula 1. The ligands LD may be derived from the oxygen-containing compound represented by Formula 1. The oxygen-containing compound represented by Formula 1 may be a compound that includes a peroxide group. The ligands LD derived from the oxygen-containing compound represented by Formula 1 may not include a hydroxy group. The ligands LD derived from the oxygen-containing compound represented by Formula 1 may not include a nitrogen atom.

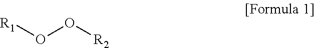

In Formula 1, R₁ and R₂ may each independently be a hydrogen atom, a substituted or unsubstituted alkyl group 1 to 30 carbon atoms, or a substituted carbonyl group, except that R₁ and R₂ may not be hydrogen atoms at a same time. In an embodiment, one of R₁ and R₂ may be an alkyl group, and the remaining one of R₁ and R₂ may be a hydrogen atom. In another embodiment, R₁ and R₂ may each independently be a substituted alkyl group 1 to 30 carbon atoms, or a substituted carbonyl group. In still another embodiment, R₁ and R₂ may be the same, provided that they are not both hydrogen atoms. However, this is only an example, and embodiments are not limited thereto.

For example, the oxygen-containing compound represented by Formula 1 may be represented by one of Formula 1-1 to Formula 1-3. Formula 1-1 may represent a case where one of R₁ and R₂ in Formula 1 is a hydrogen atom. Formula 1-2 may represent a case where R₁ and R₂ in Formula 1 are each independently a substituted or unsubstituted alkyl group having 1 to 30 carbon atoms. Formula 1-3 may represent a case where R₁ and R₂ in Formula 1 are each independently a substituted carbonyl group.

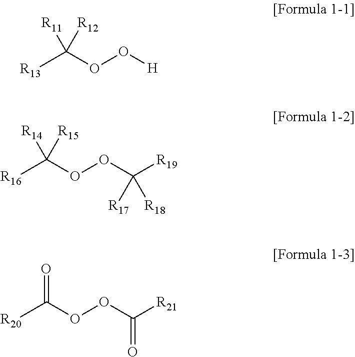

In Formula 1-1 to Formula 1-3, R₁₁ to R₂₁ may each independently be a substituted or unsubstituted alkyl group having 1 to 20 carbon atoms, or a substituted or unsubstituted aryl group having 6 to 20 ring-forming carbon atoms. For example, R₁₁ to R₁₉ may each independently be a substituted or unsubstituted methyl group or a substituted or unsubstituted phenyl group.

In an embodiment, the oxygen-containing compound represented by Formula 1 may be any compound selected from Compound Group 1. The oxygen-containing compound may include at least one compound selected from Compound Group 1:

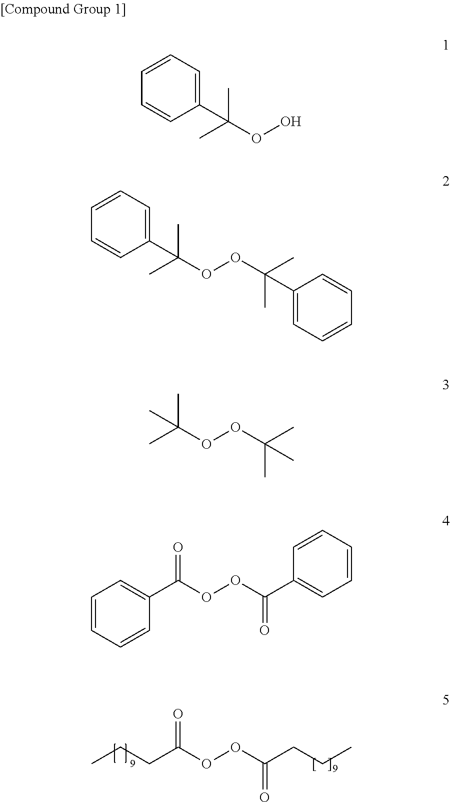

In Compound Group 1, Compound 1 may be cumene hydroperoxide, Compound 2 may be dicumyl peroxide, Compound 3 may be tert-butyl peroxide, Compound 4 may be benzoyl peroxide, and Compound 5 may be lauroyl peroxide.

In the oxygen-containing compound represented by Formula 1, the oxygen-oxygen bond is dissociated, and thus an oxygen-containing radical may be generated. For example, in the oxygen-containing compound, the oxygen-oxygen bond constituting a peroxide group is dissociated, and thus an oxygen-containing radical may be generated. The oxygen-containing radical may include an alkoxy group. The oxygen-containing radical may constitute the ligand LD bonded to the surface of the core MC. The oxygen atom in the oxygen-containing radical may include an unshared odd electron. The oxygen atom including an unshared odd electron may be directly bonded to the surface of the core MC. The oxygen-containing radical may be represented by Formula 2-1 or Formula 2-2:

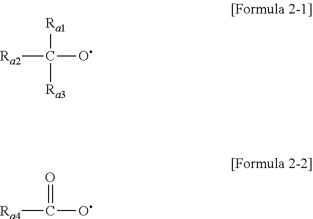

In Formula 2-1 and Formula 2-2, Rₐ₁ to Rₐ₄ may each independently be a substituted or unsubstituted alkyl group having 1 to 20 carbon atoms or a substituted or unsubstituted aryl group having 6 to 20 ring-forming carbon atoms.

FIG. 8 illustrates as an example that the oxygen-containing radical represented by Formula 2-1 is bonded to the surface MC_SF of the core MC. For example, in FIG. 8, any two among Rₐ₁ to Rₐ₃ may be an unsubstituted methyl group, and the other among Rₐ₁ to Rₐ₃ may be an unsubstituted phenyl group. However, this is only an example, and Rₐ₁ to Rₐ₃ are not limited thereto. Although not shown in FIG. 8, the oxygen-containing radical represented by Formula 2-2 may be bonded to the surface MC_SF of the core MC.

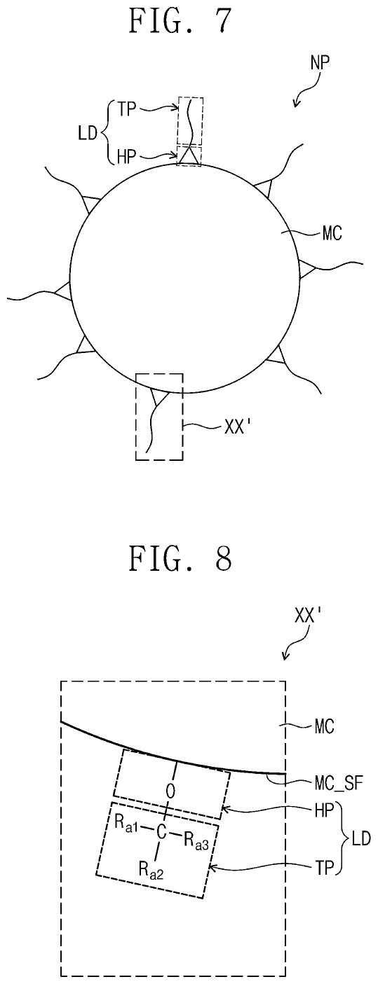

FIG. 9 is a schematic cross-sectional view of the metal nanoparticle NP-a according to another embodiment. Ligands LD and LD-a may be provided as multiple ligands, and at least one of the ligands LD and LD-a may be different. In the description of FIG. 9, the features which have been previously described with reference to FIGS. 1 to 8 will not be described again, and the differing features will be described.

The metal nanoparticle NP-a illustrated in FIG. 9 is different from the metal nanoparticle NP illustrated in FIG. 7 at least in that the metal nanoparticle NP-a may include first and second ligands LD and LD-a, which may be different from each other. FIG. 9 illustrates five of the first ligands LD and three of the second ligands LD-a, but the number of the first and second ligands LD and LD-a is not limited thereto. The positions of the first and second ligands LD and LD-a bonded is not limited to the positions shown in the FIG. 9.

In an embodiment, the first and second ligands LD and LD-a may each include an alkoxy group. The first and second ligands LD and LD-a may each include an alkoxy group directly bonded to the core MC. The first ligand LD may be different from the second ligand LD-a in the groups that are bonded to the carbon atom constituting an alkoxy group.

In an embodiment, the first and second ligands LD and LD-a may respectively include head parts HP and tail parts TP and TP-a. The head parts HP of the first and second ligands LD and LD-a may be the same. The head parts HP of the first and second ligands LD and LD-a may include an oxygen atom. The tail part TP of the first ligand LD may be different from the tail part TP-a of the second ligand LD-a. The tail parts TP and TP-a of the first and second ligands LD and LD-a, may each be respectively bonded to the oxygen atom of the head part HP and include a carbon atom constituting an alkoxy group. The groups bonded to the carbon atom in the tail part TP of the first ligand LD may be different from the groups bonded to the carbon atom in the tail part TP-a of the second ligand LD-a.

For example, the first ligand LD may be composed of an oxygen-containing radical represented by Formula 2-1 as described above, and the second ligand LD-a may be composed of an oxygen-containing radical represented by Formula 2-2 as described above. However, this is only an example, and the composition of the first and second ligands LD and LD-a is not limited thereto.

The metal nanoparticles NP according to an embodiment may include a core MC and ligands LD bonded to the core MC. The core MC may include a metal oxide. The ligand LD may include an alkoxy group, and the oxygen atom of the alkoxy group may be directly bonded to the surface MC_SF of the core MC. In the core of which the ligand LD is bonded to the surface MC_SF, the defects of the surface MC_SF may be eliminated. There may be an oxygen vacancy and surface defects in the surface of the core including a metal oxide, and when the ligand including an alkoxy group is not bonded to the surface, charges may be captured in the surface of the core during the operation of the light emitting element. In an embodiment, the charges may not be injected into the emission layer, and thus the light emitting element deteriorates. In another embodiment, the metal nanoparticle NP including the ligands LD including alkoxy groups bonded to the core MC have defects minimized (or eliminated) and may thus minimize (or prevent) the deterioration of the light emitting elements ED and ED-a and contribute to improving service life and luminous efficiency.

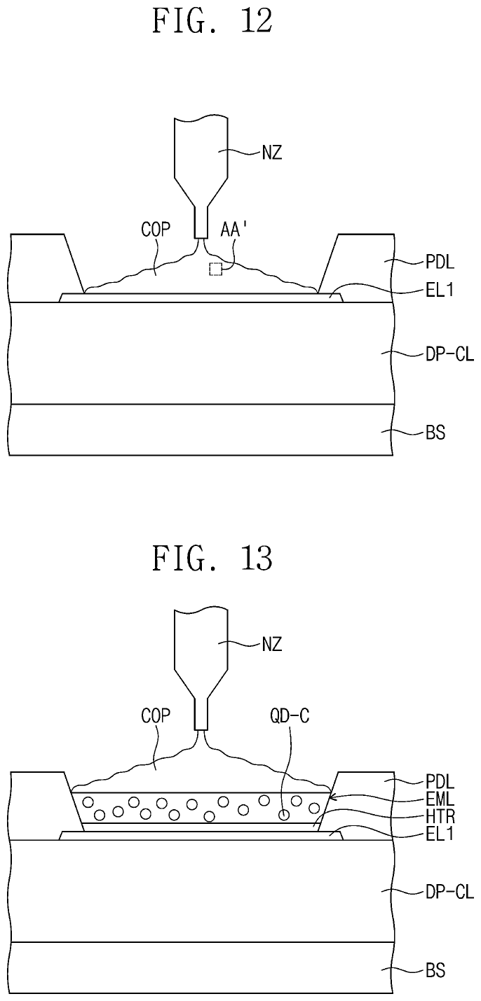

In a method for manufacturing the light emitting element according to an embodiment, which will be described later, metal nanoparticles NP may be provided by being included in a composition COP (see FIG. 14). The metal nanoparticles NP including the ligands LD bonded to the core MC exhibit excellent stability over time and may be provided by an inkjet printing method or by a dispensing method.

The light emitting element according to an embodiment may be manufactured using the method for manufacturing the light emitting element according to an embodiment. A display device according to an embodiment may include the light emitting element manufactured using the method for manufacturing the light emitting element according to an embodiment.

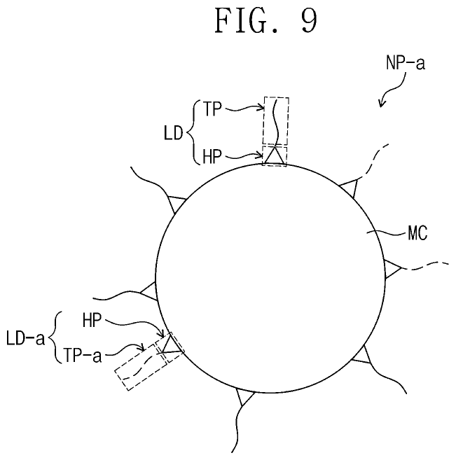

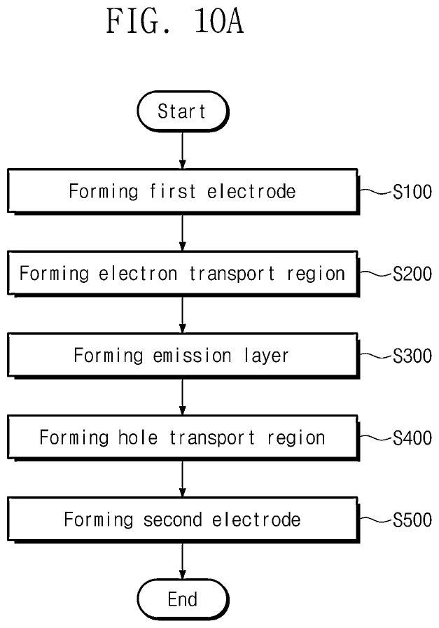

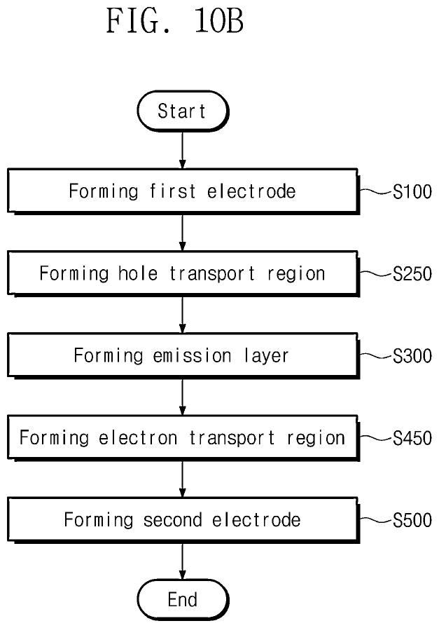

FIG. 10A is a flowchart of a method for manufacturing a light emitting element according to an embodiment. FIG. 10B is a flowchart of a method for manufacturing the light emitting element according to another embodiment. FIGS. 11 to 13 are each a schematic view of a step for manufacturing the light emitting element according to an embodiment. FIG. 14 is an enlarged schematic view of region AA′ in FIG. 12. Hereinafter, in the description of FIGS. 10A to 14, the features which have been previously described with reference to FIGS. 1 to 9 will not be described again, and the differing features will be described.

Referring to FIGS. 10A and 10B, the method for manufacturing the light emitting element according to an embodiment may include a step for forming a first electrode (S100), a step for forming an emission layer on the first electrode (S300), and a step for forming a second electrode on the emission layer (S500). The method for manufacturing the light emitting element according to an embodiment may include steps for forming an electron transport region (S200 and S450) and a step for forming a hole transport region (S400 and S250). In an embodiment, one step among the forming the electron transport region (S200 and S450) and the forming the hole transport region (S400 and S250) may be performed between the step for forming the first electrode (S100) and the step for forming the emission layer (S300), and the remaining step thereof may be performed between the step for forming the emission layer (S300) and the step for forming the second electrode (S500).

Referring to FIG. 10A, the step for forming the electron transport region (S200) may be performed between the step for forming the first electrode (S100) and the step for forming the emission layer (S300), and the step for forming the hole transport region (S400) may be performed between the step for forming the emission layer (S300) and the step for forming the second electrode (S500). The emission layer EML (see FIGS. 5A to 5D) may be formed on the electron transport region ETR (see FIGS. 5A to 5D) formed on the first electrode EL1 (see FIGS. 5A to 5D), and the second electrode EL2 (see FIGS. 5A to 5D) may be formed on the hole transport region HTR (see FIGS. 5A to 5D) formed on the emission layer EML (see FIGS. 5A to 5D).

In another embodiment, referring to FIG. 10B, the step for forming the hole transport region (S250) may be performed between the step for forming the first electrode (S100) and the step for forming the emission layer (S300), and the step for form the electron transport region (S450) may be performed between the step for forming the emission layer (S300) and the step for forming the second electrode (S500). The emission layer EML (see FIGS. 6A to 6D) may be formed on the hole transport region HTR (see FIGS. 6A to 6D) formed on the first electrode EL1 (see FIGS. 6A to 6D), and the second electrode EL2 (see FIGS. 6A to 6D) may be formed on the electron transport region ETR (see FIGS. 6A to 6D) formed on the emission layer EML (see FIGS. 6A to 6D).

In an embodiment, at least one of the steps for forming the electron transport region (S200 and S450) and the steps for forming the hole transport region (S400 and S250) may include a step for providing a composition COP (see FIG. 14) including the metal nanoparticles NP (see FIG. 14). The method for manufacturing the light emitting element according to an embodiment may include a step for preparing metal nanoparticles NP (see FIG. 11) before the step for providing the composition COP (see FIG. 14).

FIG. 11 is a schematic view of the step for preparing the metal nanoparticles NP. The metal nanoparticles NP may be produced from preliminary metal nanoparticles P-NP. The preliminary metal nanoparticles P-NP may include a core MC and preliminary ligands P-LD bonded to the core MC. For example, the preliminary ligands P-LD may include a hydroxy group.

The preliminary metal nanoparticles P-NP may be dispersed in an aqueous solvent. The aqueous solvent may include a hydroxy group. For example, the aqueous solvent may include methanol or ethanol. However, this is only an example, and the aqueous solvent is not limited to any particular embodiment, as long as it allows the preliminary metal nanoparticles P-NP to be readily dispersed.

The oxygen-containing compound represented by Formula 1 as described above may be provided to the preliminary metal nanoparticle P-NP. “Step 1” in FIG. 11 may represent a step for providing the oxygen-containing compound represented by Formula 1 as described above. R₁ and R₂ in Formula 1 may be the same as described herein.

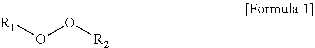

In an embodiment, in the oxygen-containing compound represented by Formula 1, the oxygen-oxygen bond may be dissociated to form an oxygen-containing radical, and the oxygen-containing radical may be bonded to the core MC, and thus the metal nanoparticle NP containing the core MC and the ligands LD may be produced.

When the oxygen-containing radical is formed and is bonded to the core MC, it may be performed at a first temperature. When the oxygen-containing radical is formed and is bonded to the core MC, a stirrer may be used.

The first temperature is the temperature at which heat is provided, and may be a temperature higher than an auto-decomposition temperature of the oxygen-containing compound. The auto-decomposition temperature may be the temperature at which the oxygen-containing compound decomposes for itself to form an oxygen-containing radical. For example, an auto-decomposition temperature of the oxygen-containing compound may be about 100° C. At the first temperature, the oxygen-containing radical may be bonded to the core MC. The oxygen-containing radical may be bonded to the core MC, and the preliminary ligands P-LD may be removed from the core MC. The bond between the core MC and the preliminary ligands P-LD may be dissociated. The produced metal nanoparticles NP may be provided by being included in the composition COP (see FIG. 14).

FIG. 12 is a schematic cross-sectional view of the step for providing a composition COP including metal nanoparticles NP (see FIG. 14) according to an embodiment on the first electrode EL1. The first electrode EL1 may be disposed on the base layer BS. For example, the first electrode EL1 may be disposed on the circuit layer DP-CL disposed on the base layer BS. When the manufacture step illustrated in FIG. 12 is performed, the light emitting elements ED and ED-a to ED-c illustrated in FIGS. 5A to 5D may be manufactured.

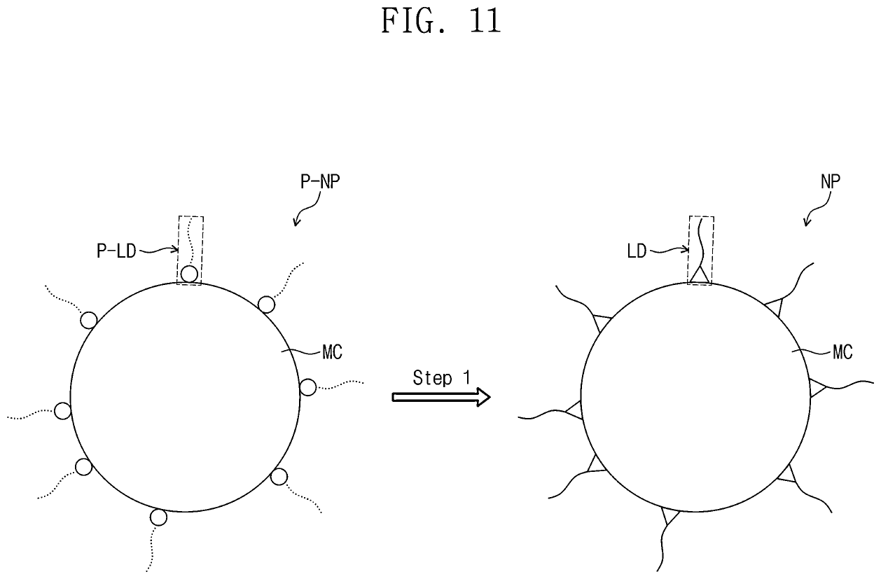

FIG. 13 is a schematic cross-sectional view of the step for providing a composition COP including metal nanoparticles NP (see FIG. 14) according to an embodiment on the emission layer EML. FIG. 13 is different from FIG. 12 at least in that the step for forming the emission layer EML may be performed before the step for providing the composition COP. When the manufacture step illustrated in FIG. 13 is performed, the light emitting elements ED-d to ED-g illustrated in FIGS. 6A to 6D may be manufactured.

Referring to FIG. 13, the emission layer EML may be formed by providing a quantum dot composition including quantum dots QD-C. The quantum dot composition may include quantum dots QD-C and a solvent in which the quantum dots QD-C are dispersed. For example, the quantum dots QD-C may be dispersed in the organic solvent and provided by an inkjet printing method or provided by a dispensing method.

FIG. 14 is an enlarged schematic view of AA′ region of FIG. 12, and may be a view schematically illustrating the composition COP. Hereinafter, the description of the composition COP may be equally applied to FIGS. 12 and 13. Hereinafter, it will be described with reference to FIGS. 12 to 14.

In an embodiment, the composition COP including the metal nanoparticles NP may be provided by an inkjet printing method or a dispensing method. In an embodiment, the metal nanoparticle NP may include a core MC and ligands LD bonded to the surface MC_SF (see FIG. 8) of the core MC. The core MC may include a metal oxide, and the ligands LD may be derived from the oxygen-containing compound represented by Formula 1, and may include alkoxy groups. The metal nanoparticle NP which may be derived from the oxygen-containing compound represented by Formula 1 and is composed of ligands LD including alkoxy groups exhibit excellent stability over time, and may be provided by an inkjet printing method or a dispensing method. Accordingly, the method for manufacturing the light emitting element according to an embodiment may exhibit excellent manufacture reliability and efficiency.

When the ligands LD including alkoxy groups are not bonded to the core MC and are provided being dispersed in the composition COP (see FIG. 14), the ligands LD may auto-decompose and the stability over time may deteriorate. The ligands LD including alkoxy groups decompose for themselves at a temperature (e.g., a predetermined or a selectable temperature) to form radicals, and when the formed radicals are dispersed, the stability over time is deteriorated. Accordingly, in an embodiment, when the ligands LD including alkoxy groups are not bonded to the core MC and are provided being dispersed in the composition COP, the ligands LD may not be suitable for being provided by an inkjet printing method or by a dispensing method. In another embodiment, the metal nanoparticles NP to which the ligands LD derived from the oxygen-containing compound represented by Formula 1 as described above and including alkoxy groups are directly bonded to the core MC, may exhibit excellent stability over time.

FIGS. 12 and 13 illustrate that the composition COP is provided through a nozzle NZ, but the device for providing the composition COP is not limited thereto. The composition COP including the metal nanoparticles NP having excellent stability over time may be provided by an inkjet printing method or a dispensing method.

Referring to FIG. 14, the composition COP may include a first solvent CV in which the metal nanoparticles NP are dispersed. The first solvent CV may be provided as a material in which the metal nanoparticles NP are readily dispersed. For example, the first solvent CV may be a material containing a hydroxy group. However, this is only an example, and the first solvent CV is not limited thereto.

FIGS. 12 to 14 illustrate that the composition COP including the metal nanoparticles NP according to an embodiment may be provided in order to form the electron transport region ETR (see FIGS. 5A to 6D), but embodiments are not limited thereto. Although not shown in the drawings, the composition COP including the metal nanoparticles NP according to an embodiment may be provided in order to form the hole transport region HTR (see FIGS. 5C, 5D, 6C, and 6D).

Hereinafter, with reference to Examples and Comparative Examples, the light emitting element according to an embodiment will be described in detail. The Examples and Comparative Examples described below are only illustrations to assist in understanding the disclosure, and the scope of the embodiments is not limited thereto.

### Examples and Comparative Examples

### 1. Manufacture of the Light Emitting Element

The light emitting elements of the Examples and Comparative Examples were manufactured by the following method. On a glass substrate which was cut into a size of 50 mm×50 mm×0.7 mm, ITO/Ag/ITO were deposited as a first electrode. On the first electrode, poly(3,4-ethylenedioxythiophene)/poly(4-styrenesulfonate) (PEDOT/PSS) were deposited to form a 600-Å thick film and was baked at 140° C. for 10 minutes to form a hole injection layer. On the hole injection layer, poly[(9,9-dioctylfluorenyl-2,7-diyl)-co-(4,4′-(N-(4-sec-butylphenyl)diphenylamine)](TFB) was deposited to form a 400-Å thick film and was baked at 140° C. for 10 minutes to form a hole transport layer.

On the hole transport layer, InP/ZnSe/ZnS were provided to form a 200-Å thick film and was baked at 140° C. for 10 minutes to form an emission layer. On the emission layer, a composition including metal nanoparticles was provided to form a 200-Å thick electron transport layer. The materials for forming each of the electron transport layer, emission layer, hole transport layer, and hole injection layer were provided in the form of a composition by using spin coating facilities. On the electron injection layer, AgMg was deposited in vacuum with an evaporator to form a 200-Å thick second electrode.

The light emitting elements of Comparative Examples 1 and 2 and Example 1 are different in the composition provided during the formation of the electron transport layer. In the light emitting elements of Comparative Examples 1 and 2 and Example 1, the composition provided during the formation of the electron transport layer includes metal nanoparticles, the cores of the metal nanoparticles are the same and only the ligands are different. The core of the metal nanoparticle includes ZnMgO, and is produced by a low-temperature sol-gel method.

The light emitting element of Comparative Example 1 includes an electron transport layer formed by providing the composition including the metal nanoparticles of Comparative Example 1 that does not include ligands derived from the oxygen-containing compound represented by Formula 1. The metal nanoparticle of Comparative Example 1 has a ligand composed of a radical represented by Formula X-1, the ligand being bonded to the surface thereof.

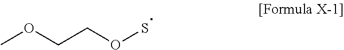

In the metal nanoparticle of Comparative Example 1, the ligand includes an alkoxy group. However, the sulfur atom is directly bonded to the surface of the metal nanoparticle, while the oxygen atom of the alkoxy group is not directly bonded to the surface of the metal nanoparticle.

The composition provided during the formation of the electron transport layer in the light emitting element of Comparative Example 2 includes radicals derived from Compound 2 of Compound Group 1 as described above, but the radicals are not bonded to the core of the metal nanoparticle and are provided in a dispersed form in the composition. For example, in Comparative Example 2, the oxygen-containing compound was not provided during the preparation of the metal nanoparticles, but was added to the composition including the metal nanoparticles.

In the light emitting element of Example 1, the electron transport layer was formed by providing a composition including metal nanoparticles according to an embodiment. The light emitting element of Example 1 includes an electron transport layer formed from the composition including metal nanoparticles in which ligands derived from Compound 2 of Compound Group 1 are bonded to the core. The composition was stirred for one hour such that radicals were formed and bonded to the core. The metal nanoparticles were produced at a first temperature higher than the auto-decomposition temperature of the oxygen-containing compound. Formula Z1 represents a radical derived from Compound 2:

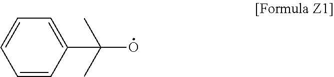

### 2. Evaluation of Light Emitting Element

Table 1 shows an evaluation of driving voltages and luminous efficiencies in the light emitting elements of Comparative Examples and Example. The driving voltage was evaluated on the basis of a current density of 5 mA/cm², and the luminous efficiency was evaluated on the basis of a brightness of 2,000 nit. The driving voltage and luminous efficiency were measured by using Keithley SMU 236.

TABLE 1

| Examples of | Driving voltage (V, | Luminous efficiency |
|---|---|---|
| manufactured elements | @ 5 mA/cm²) | (cd/A, @ 2000 nit) |
| Comparative Example 1 | 4.6 | 50.6 |
| Comparative Example 2 | 5.2 | 69.0 |
| Example 1 | 4.0 | 71.8 |

Referring to Table 1, it may be seen that the light emitting element of Example 1 has a lower driving voltage and higher luminous efficiency than the light emitting elements of Comparative Examples 1 and 2. The light emitting element of Example 1 includes ligands derived from the oxygen-containing compound represented by Formula 1 according to an embodiment, and the ligands include alkoxy groups. In the light emitting element of Example 1, the electron transport layer includes the metal nanoparticles composed of ligands including alkoxy groups directly bonded to the surface of the core. Accordingly, in an embodiment, it may be seen that the light emitting element including the metal nanoparticles composed on ligands derived from the oxygen-containing compound represented by Formula 1 and including alkoxy groups exhibits low driving voltage and high efficiency.

In the light emitting element of Comparative Example 1, the electron transport layer includes the metal nanoparticles, but does not include ligands derived from the oxygen-containing compound represented by Formula 1. In the light emitting element of Comparative Example 2, the electron transport layer includes the metal nanoparticles, but the radicals derived from the oxygen-containing compound represented by Formula 1 are not bonded to the core and are provided in a dispersed form. Accordingly, the light emitting elements of Comparative Examples 1 and 2 show relatively high driving voltages and low luminous efficiencies.

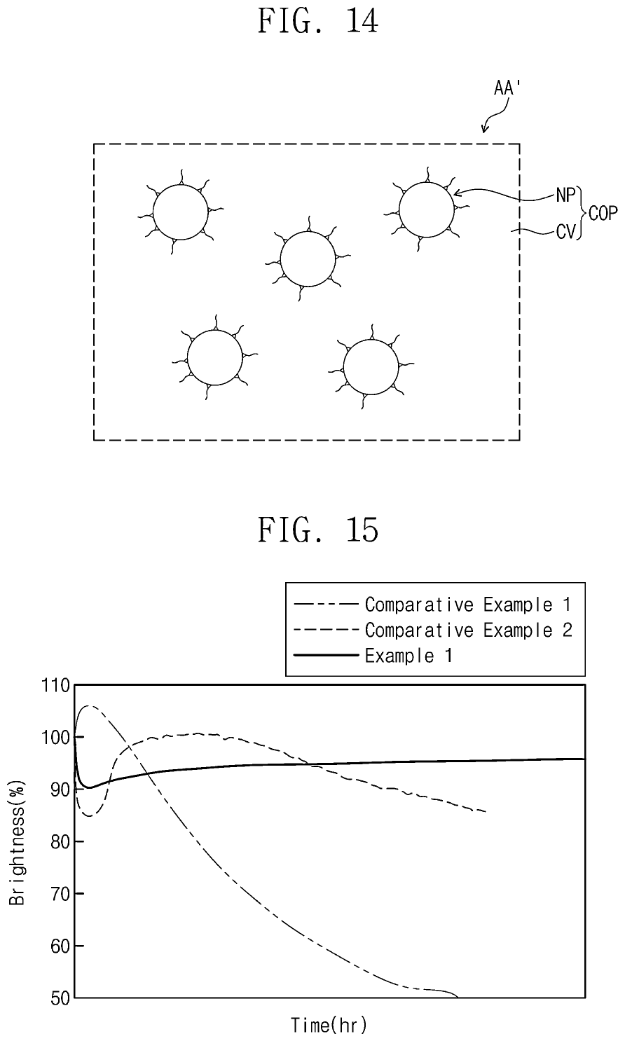

FIG. 15 is a graph showing relative brightness ratio over time in the light emitting elements of Comparative Examples and Example. The graph in FIG. 15 is the result of measurement by using a luminance meter PR650.

Referring to FIG. 15, it may be seen that compared to the light emitting elements of Comparative Examples 1 and 2, the light emitting element of Example 1 exhibits uniform brightness over time, and the uniform brightness is maintained for a relatively long period of time. It may be seen that the light emitting element of Example 1 has a service life longer than the light emitting elements of Comparative Examples 1 and 2. In the light emitting element of Example 1, the electron transport layer includes the metal nanoparticles composed of ligands including alkoxy groups directly bonded to the surface of the core. Accordingly, in an embodiment, it may be seen that the light emitting element including the metal nanoparticles composed on ligands derived from the oxygen-containing compound represented by Formula 1 and including alkoxy groups exhibits a long service life characteristic.

In the light emitting element of Comparative Example 1, the electron transport layer includes the metal nanoparticles, but does not include ligands derived from the oxygen-containing compound represented by Formula 1. Accordingly, the light emitting element of Comparative Example 1 shows a large decrease in the brightness over time and a short service life.

In the light emitting element of Comparative Example 2, the electron transport layer includes the metal nanoparticles, but the ligands derived from the oxygen-containing compound represented by Formula 1 are provided in a dispersed form rather than being bonded to the core. The light emitting element of Comparative Example 2 has a large degree of change in the brightness due to a decrease in the stability of the light emitting element over time, and exhibits relatively low brightness over time.

The display device according to an embodiment may include the light emitting element according to an embodiment. The light emitting element according to an embodiment may be manufactured by the method for manufacturing the light emitting element according to an embodiment. The method for manufacturing the light emitting element according to an embodiment may include a step for providing a composition including metal nanoparticles to form an electron transport region and/or a hole transport region. In the light emitting element according to an embodiment, at least one of the electron transport region and the hole transport region may include metal nanoparticles composed of a core and ligands bonded to the core. The ligands may be derived from the oxygen-containing compound represented by Formula 1 and may include alkoxy groups. Accordingly, the composition including metal nanoparticles exhibits excellent stability over time and may be provided by an inkjet printing method or by a dispensing method. The method for manufacturing the light emitting element according to an embodiment may exhibit excellent manufacture reliability and efficiency.

The light emitting element according to an embodiment including the metal nanoparticles may exhibit characteristics of low driving voltage, high efficiency, and long service life. The display device including the light emitting element according to an embodiment may exhibit excellent display efficiency and display service life.

The light emitting element and the display device including the light emitting element according to an embodiment may exhibit excellent luminous efficiency and service life by including a metal nanoparticle composed of ligands including alkoxy groups.

The method for manufacturing the light emitting element according to an embodiment includes providing a metal nanoparticle composed of ligands including alkoxy groups, and thus may exhibit excellent manufacture reliability and efficiency.

Embodiments have been disclosed herein, and although terms are employed, they are used and are to be interpreted in a generic and descriptive sense only and not for purposes of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A light emitting element comprising:
a first electrode;
a second electrode disposed on the first electrode;
an emission layer disposed between the first electrode and the second electrode and including quantum dots;
a hole transport region disposed between the first electrode and the second electrode; and
an electron transport region disposed between the first electrode and the second electrode, wherein
the emission layer is disposed between the hole transport region and the electron transport region,
at least one of the hole transport region and the electron transport region comprises metal nanoparticles,
the metal nanoparticles comprise:
a core including a metal oxide; and
a ligand bonded to the core, the ligand including an alkoxy group, and
the alkoxy group is derived from an oxygen-containing compound represented by Formula 1: 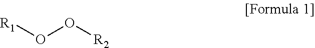
wherein in Formula 1,
R₁ and R₂ are each independently a hydrogen atom, a substituted or unsubstituted alkyl group having 1 to 30 carbon atoms, or a substituted carbonyl group, except that R₁ and R₂ are not hydrogen atoms at a same time.

2. The light emitting element of claim 1, wherein the alkoxy group is directly bonded to a surface of the core.

3. The light emitting element of claim 1, wherein the oxygen-containing compound is selected from Compound Group 1:

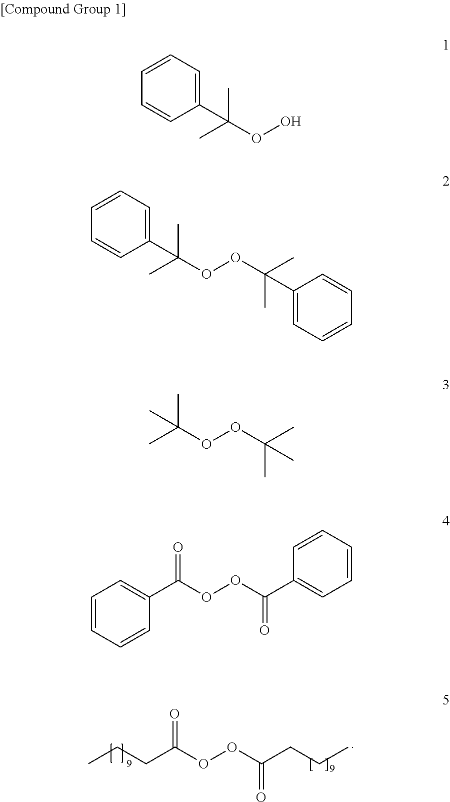

4. The light emitting element of claim 1, wherein
the ligand is provided as a plurality of ligands, and
at least one of the ligands is different from the remainder.

5. The light emitting element of claim 1, wherein:
the metal oxide comprises at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or
the metal oxide is represented by Formula M-1:
Zn_{(1-q)}Me_{q}O [Formula M-1]
wherein in Formula M-1,
q is a real number from 0 to 0.3, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba.

6. The light emitting element of claim 1, wherein
the electron transport region is disposed between the first electrode and the emission layer, and
the hole transport region is disposed between the emission layer and the second electrode.

7. The light emitting element of claim 1, wherein
the hole transport region is disposed between the first electrode and the emission layer, and
the electron transport region is disposed between the emission layer and the second electrode.

8. The light emitting element of claim 1, wherein
the electron transport region comprises:
an electron injection layer; and
an electron transport layer disposed between the first electrode and the emission layer or between the emission layer and the second electrode, and
at least one of the electron injection layer and the electron transport layer comprises the metal nanoparticles.

9. The light emitting element of claim 1, wherein
the hole transport region comprises:
a hole injection layer; and
a hole transport layer disposed between the first electrode and the emission layer or between the emission layer and the second electrode, and
at least one of the hole injection layer and the hole transport layer comprises the metal nanoparticles.

10. A method for manufacturing a light emitting element, the method comprising:
forming a first electrode;
forming an emission layer on the first electrode;
forming a second electrode on the emission layer;
forming a hole transport region; and
forming an electron transport region, wherein
one step among the forming of the hole transport region and the forming of the electron transport region is performed between the forming of the first electrode and the forming of the emission layer,
the remaining step among the forming of the hole transport region and the forming of the electron transport region is performed between the forming of the emission layer and the forming of the second electrode,
at least one of the forming of the hole transport region and the forming of the electron transport region comprises providing a composition including metal nanoparticles,
the metal nanoparticles comprise:
a core including a metal oxide; and
a ligand bonded to the core, the ligand including an alkoxy group, and
the alkoxy group is derived from an oxygen-containing compound represented by Formula 1: 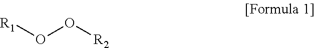
wherein in Formula 1,
R₁ and R₂ are each independently a hydrogen atom, a substituted or unsubstituted alkyl group having 1 to 30 carbon atoms, or a substituted carbonyl group, except that R₁ and R₂ are not hydrogen atoms at a same time.

11. The method of claim 10, further comprising:
producing the metal nanoparticles before the providing of the composition, wherein
the producing of the metal nanoparticles comprises:
preparing preliminary metal nanoparticles including the core and a preliminary ligand bonded to the core;
providing the oxygen-containing compound to the preliminary metal nanoparticles; and
bonding, to the core, the ligand generated by the dissociation of an oxygen-oxygen bond of the oxygen-containing compound.

12. The method of claim 11, wherein
the bonding of the ligand to the core is performed at a first temperature at which heat is provided,
the first temperature is higher than an auto-decomposition temperature of the oxygen-containing compound, and
the auto-decomposition temperature is defined as a temperature at which the oxygen-containing compound is decomposed for itself to form an oxygen-containing radical.

13. The method of claim 11, wherein the preliminary ligand is removed from the core in the bonding of the ligand to the core.

14. The method of claim 11, wherein the preliminary metal nanoparticles are provided by being dispersed in an aqueous solvent containing a hydroxy group.

15. The method of claim 10, wherein the composition is provided by an inkjet printing method or by a dispensing method.

16. The method of claim 10, wherein the oxygen-containing compound is selected from Compound Group 1:

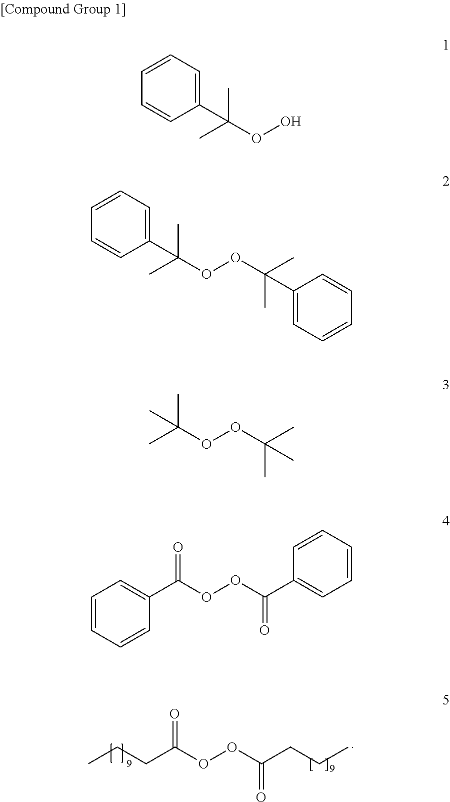

17. The method of claim 10, wherein:
the metal oxide comprises at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or
the metal oxide is represented by Formula M-1:
Zn_{(1-q)}Me_{q}O [Formula M-1]
wherein in Formula M-1,
q is a real number from 0 to 0.3, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba.

18. A display device comprising:
a display element layer disposed on a base layer, wherein
the display element layer comprises:
a light emitting element; and
a pixel defining film in which a pixel opening is defined,
the light emitting element comprises:
a first electrode disposed in the pixel opening;
a second electrode disposed on the first electrode;
an emission layer disposed between the first electrode and the second electrode and including quantum dots;
a hole transport region disposed between the first electrode and the second electrode; and
an electron transport region spaced disposed between the first electrode and the second electrode,
the emission layer is disposed between the hole transport region and the electron transport region,
at least one of the hole transport region and the electron transport region comprises metal nanoparticles,
the metal nanoparticles comprise:
a core including a metal oxide; and
a ligand bonded to the core, the ligand including an alkoxy group, and
the alkoxy group is derived from an oxygen-containing compound represented by Formula 1: 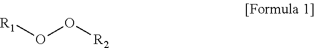
wherein in Formula 1,
R₁ and R₂ are each independently a hydrogen atom, a substituted or unsubstituted alkyl group having 1 to 30 carbon atoms, or a substituted carbonyl group, and except that R₁ and R₂ are not hydrogen atoms at a same time.

19. The display device of claim 18, wherein the alkoxy group is directly bonded to a surface of the core.

20. The display device of claim 18, wherein the oxygen-containing compound is selected from Compound Group 1:

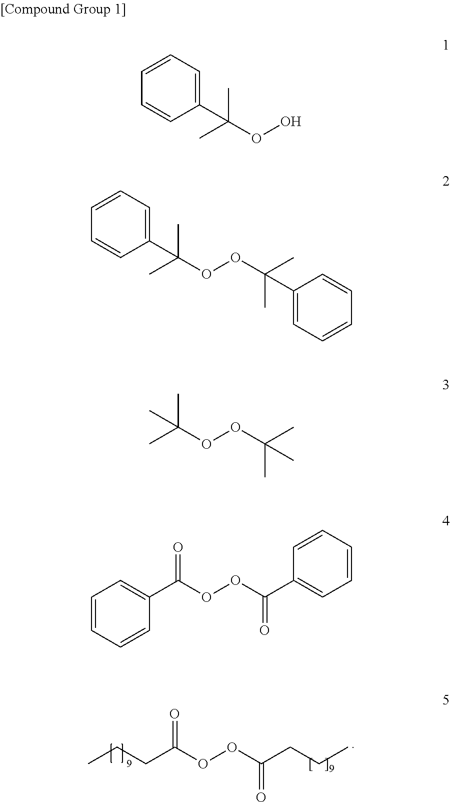

21. The display device of claim 18, wherein:
the metal oxide comprises at least one of SnO, SnO₂, CuGaO₂, Ga₂O₃, Cu₂O, SrCu₂O₂, SrTiO₃, CuAlO₂, Ta₂O₅, NiO, BaSnO₃, and TiO₂; or
the metal oxide is represented by Formula M-1:
Zn_{(1-q)}Me_{q}O [Formula M-1]
wherein in Formula M-1,
q is a real number from 0 to 0.3, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pb, Pd, Ag, In, Sn(II), Sn(IV), Sb, or Ba.

22. The display device of claim 18, wherein
the electron transport region comprises:
an electron injection layer; and
an electron transport layer disposed between the first electrode and the emission layer or between the emission layer and the second electrode, and
at least one of the electron injection layer and the electron transport layer comprises the metal nanoparticles.

23. The display device of claim 18, wherein
the hole transport region comprises:
a hole injection layer; and
a hole transport layer disposed between the first electrode and the emission layer or between the emission layer and the second electrode, and
at least one of the hole injection layer and the hole transport layer comprises the metal nanoparticles.
